(19) United States
(12) Patent Application Publication
(10) Pub. No.: US 2026/0231405 A1
(43) Pub. Date: Aug. 6, 2026

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Seung Yoon Kim, Suwon-si (KR); Dong-Won Kim, Suwon-si (KR); Chang-Sup Lee, Suwon-si (KR)

(21) Appl. No.: 19/309,812

(22) Filed: Aug. 26, 2025

(30) Foreign Application Priority Data
Jan. 31, 2025 (KR) 10-2025-0012597

(51) Int. Cl. H10B 41/27; H01L 23/00; H01L 25/18; H10B 41/35; H10B 41/41; H10B 43/27; H10B 43/35; H10B 43/40; H10B 80/00; H10D 80/30

(52) U.S. Cl. CPC H10B 41/27; H10B 41/35; H10B 41/41; H10B 43/27; H10B 43/35; H10B 43/40; H10B 80/00; H10D 80/30; H10W 90/00; H10W 90/20; H10W 90/24; H10W 90/732; H10W 90/734; H10W 90/752; H10W 90/754

(57) ABSTRACT

A semiconductor includes a substrate; a gate stacking structure including interlayer insulating layers and gate electrodes alternately stacked on the substrate; a channel structure extending through the gate stacking structure; and gate contact parts each penetrating a portion of the gate stacking structure to be electrically connected to the gate electrodes, where the gate stacking structure includes a first gate stacking structure, a second gate stacking structure, and a first upper insulation layer positioned between the first gate stacking structure and the second gate stacking structure, which are sequentially stacked on the substrate. The gate contact part electrically connected the gate electrode of the first gate stacking structure each includes a stepped part and a bent part in which the width of the gate contact part discontinuously varies in each, and the stepped part and bent part are positioned within the first upper insulation layer.

### CROSS-REFERENCE TO RELATED APPLICATION

This application claims priority to and the benefit of Korean Patent Application No. 10-2025-0012597 filed with the Korean Intellectual Property Office on Jan. 31, 2025, the entire contents of which are incorporated herein by reference.

### BACKGROUND

In electron systems that require a data storage, semiconductor devices capable of storing a high-capacity data are required. Accordingly, methods to increase the data storage capacity of the semiconductor devices are being researched. For example, as one of the methods for increasing the data storage capacity of the semiconductor device, the semiconductor device including memory cells arranged three-dimensionally instead of two-dimensionally is being proposed.

### SUMMARY

Implementations according to this disclosure provides a semiconductor device and an electronic system including the same that may improve a productivity and a reliability.

An aspect of the present disclosure provides a semiconductor device that includes: a substrate; a gate stacking structure including a plurality of interlayer insulating layers and a plurality of gate electrodes alternately stacked on the substrate; a channel structure extending through the gate stacking structure; and a plurality of gate contact parts each penetrating a portion of the gate stacking structure to be electrically connected to the plurality of gate electrodes, where the gate stacking structure includes a first gate stacking structure, a second gate stacking structure, and a first upper insulation layer positioned between the first gate stacking structure and the second gate stacking structure, which are sequentially stacked on the substrate, the gate contact part electrically connected the gate electrode of the first gate stacking structure each include a stepped part and a bent part in which the width of the gate contact part discontinuously varies in each, and the stepped part and bent part are positioned within the first upper insulation layer.

Another aspect of the present disclosure provides a semiconductor device that includes: a substrate; a gate stacking structure including a plurality of interlayer insulating layers and a plurality of gate electrodes alternately stacked on the substrate; a channel structure extending through the gate stacking structure; and a plurality of gate contact parts each penetrating a portion of the gate stacking structure to be electrically connected to the plurality of gate electrodes, where the gate stacking structure includes a first gate stacking structure, a second gate stacking structure, and a third gate stacking structure sequentially stacked from the substrate, a first upper insulation layer is positioned between the first gate stacking structure and the second gate stacking structure, a second upper insulation layer is positioned between the second gate stacking structure and the third gate stacking structure, a gate contact part electrically connected to the gate electrode positioned in the first gate stacking structure includes a bent part and a stepped part positioned within the first upper insulation layer, and a bent part and a stepped part positioned within the second upper insulation layer, the gate contact part electrically connected to the gate electrode positioned in the second gate stacking structure includes a bent part and a stepped part positioned within the second upper insulation layer, and the gate contact part electrically connected to the gate electrode positioned in the third gate stacking structure penetrates a part of the third gate stacking structure.

Another aspect of the present disclosure provides an electron system that includes: a main substrate; a semiconductor device on the main substrate; and a controller electrically connected to the semiconductor device on the main substrate, where the semiconductor device includes a substrate; a gate stacking structure including a plurality of interlayer insulating layers and a plurality of gate electrodes alternately stacked on the substrate; a channel structure extending through the gate stacking structure; and a plurality of gate contact parts each penetrating a portion of the gate stacking structure to be electrically connected to the plurality of gate electrodes, the gate stacking structure includes a first gate stacking structure and a second gate stacking structure, which are stacked with a first upper insulation layer therebetween, and the gate contact part electrically connected to the gate electrode of the first gate stacking structure includes a stepped part and a bent part, each positioned within the first upper insulation layer and each having the width of the gate contact part varied discontinuously.

Another aspect of the present disclosure provides a manufacturing method of a semiconductor device. The manufacturing method includes: forming a first sacrificial stacking part by alternately stacking a plurality of interlayer insulating layers and a plurality of sacrificial insulation layers on a substrate, where the first sacrificial stacking part includes a connection region and a cell array region; forming a first channel penetration part penetrating the first sacrificial stacking part in the cell array region, forming a first upper insulation layer and a plurality of first etching stop patterns on first sacrificial stacking part, forming a second sacrificial stacking part by alternately laminating a plurality of interlayer insulating layers and a plurality of sacrificial insulation layers on the first upper insulation layer; simultaneously forming a second channel penetration portion penetrating the cell array region of the second sacrificial stacking part and a second gate penetration portion penetrating the connection region of the second sacrificial stacking part, and forming a first gate penetration portion that is in contact with each sacrificial insulation layer of the first sacrificial stacking part through the second gate penetration portion.

In some implementations, in forming the first upper insulation layer and a plurality of first etching stop patterns on the first sacrificial stacking part, the first etching stop pattern may be formed to be in contact with the first channel penetration portion.

In some examples, in simultaneously forming the second channel penetration portion penetrating the cell array region of the second sacrificial stacking part and the second gate penetration portion penetrating the connection region of the second sacrificial stacking part, the second gate penetration portion may be formed up to the upper surface of the first etching stop pattern.

In some implementations, the first etching stop pattern may be formed within the first upper insulation layer.

In some implementations, the first gate penetration portion and the second gate penetration portion may have a shape that the widths become narrower (or at least partially narrower) as they approach (e.g., approach toward) the substrate, and may include a bent part due to the width difference between the first gate penetration portion and the second gate penetration portion.

In some implementations, the first etching stop pattern may have a shape that the width becomes narrower (or at least partially narrower) as it approaches the substrate.

In some implementations, in forming the first gate penetration portion in contact with each sacrificial insulation layer of the first sacrificial stacking part through the second gate penetration portion, the second gate penetration portion in contact with each sacrificial insulation layer of the second sacrificial stacking part may be simultaneously formed.

In some implementations, in forming the first upper insulation layer and the plurality of first etching stop patterns on the first sacrificial stacking part, the number of the first etching stop patterns formed in the connection region may be equal to the number of the sacrificial insulation layers positioned on the first sacrificial stacking part.

In some implementations, in forming the first upper insulation layer and the plurality of first etching stop patterns on the first sacrificial stacking part, the thickness of the first upper insulation layer may be thicker than the thickness of the interlayer insulating layer.

In some implementations, the semiconductor device that may improve a productivity and a reliability and the electron system including the same are provided.

### BRIEF DESCRIPTION OF THE DRAWINGS

FIG. 1 is a cross-sectional view schematically illustrating an example of a semiconductor device.

FIG. 2 is an enlarged cross-sectional view of an example of a channel structure of the semiconductor device illustrated in FIG. 1.

FIG. 3 is a cross-sectional view showing an example of a connection region of a cell region included in the semiconductor device illustrated in FIG. 1.

FIG. 4 is a cross-sectional view showing an example of a first gate contact part shown in FIG. 3.

FIG. 5 is a cross-sectional view illustrating the thirteenth to seventeenth gate contact parts illustrated in FIG. 3.

FIG. 6 is a cross-sectional view illustrating the twenty-fifth and twenty-sixth gate contact parts illustrated in FIG. 3.

FIG. 7 is a view illustrating the same region as FIG. 1 according to some implementations.

FIG. 8 to FIG. 17 are partial cross-sectional views illustrating an example of a manufacturing method of a semiconductor device.

FIG. 18 is a schematic view of an example of an electronic system including a semiconductor device.

FIG. 19 is a perspective view schematically illustrating an example of an electronic system including a semiconductor device.

FIG. 20 is a cross-sectional view schematically illustrating an example of a semiconductor package.

### DETAILED DESCRIPTION

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

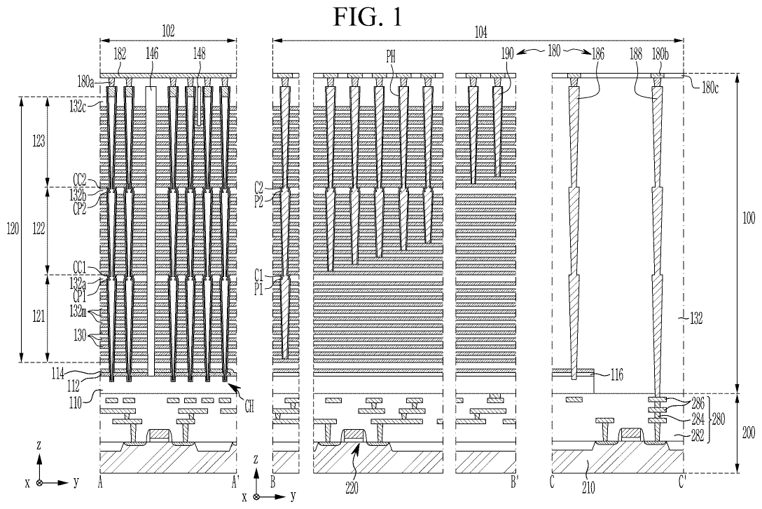

Hereinafter, a semiconductor device and a manufacturing method thereof according to some implementations are described in detail with reference to FIG. 1 to FIG. 20.

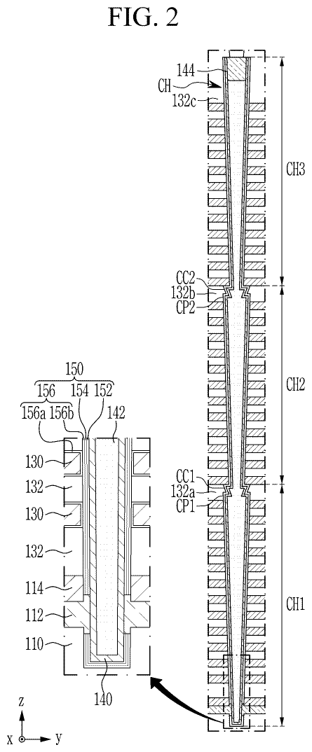

FIG. 1 is a cross-sectional view schematically illustrating a semiconductor device according to some implementations. FIG. 2 is an enlarged cross-sectional view of an example of a channel structure CH included in the semiconductor device illustrated in FIG. 1. A-A′, B-B′ and C-C′ in FIG. 1 are indicated for clear understanding and conceptually illustrates the positions of a source contact part 186 and an input/output connection wire 188.

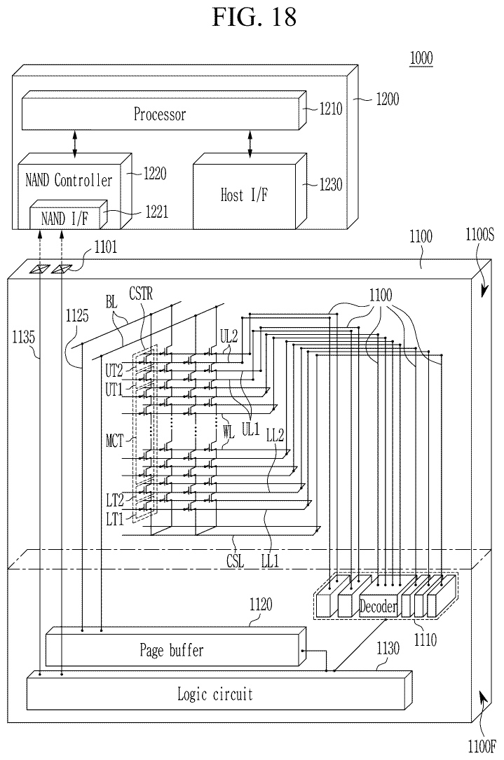

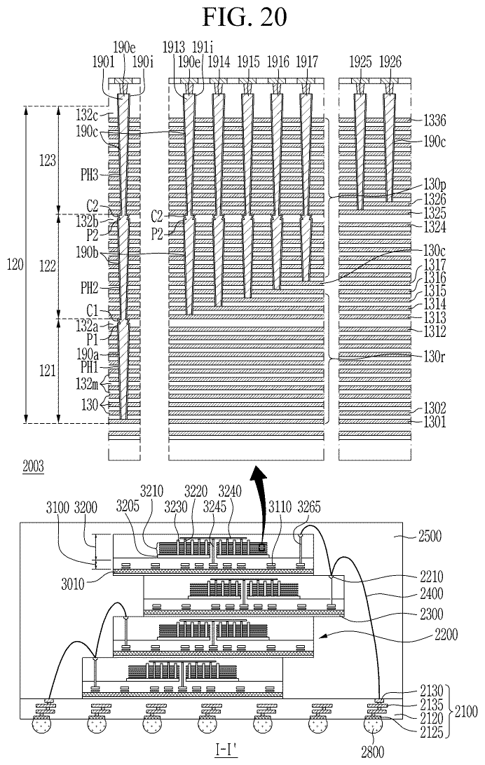

Referring to FIG. 1 and FIG. 2, a semiconductor device according to some implementations may include a cell region 100 having a memory cell structure and a circuit region 200 having a peripheral circuit structure that controls the operation of the memory cell structure. For example, the circuit region 200 and the cell region 100 may be portions corresponding to a first structure 1100F and a second structure 1100S of the semiconductor device 1100 included in an electron system 1000 illustrated in FIG. 18, respectively. Alternatively, the circuit region 200 and the cell region 100 may each be portions including the first structure 3100 and the second structure 3200 of the semiconductor chip 2200 illustrated in FIG. 20.

Here, the circuit region 200 may include a peripheral circuit structure formed on a first substrate 210, and the cell region 100 may include a gate stacking structure 120 and a channel structure CH formed on a second substrate 110 as a memory cell structure. A circuit wire part 280 may be provided in the circuit region 200, and a cell wire part 180 electrically connected to the memory cell structure may be provided in the cell region 100.

In some implementations, the cell region 100 may be positioned on the circuit region 200. According to this, the area corresponding to the circuit region 200 does not need to be secured separately from the cell region 100, so the area of the semiconductor device may be reduced. In some implementations, the circuit region 200 may be positioned next to the cell region 100. Various other modifications are possible.

The circuit region 200 may include a first substrate 210, a circuit element 220 and a circuit wire part 280 formed on one surface (the upper surface of FIG. 1) of the first substrate 210.

The first substrate 210 may be a semiconductor substrate including a semiconductor material. For example, the first substrate 210 may be a semiconductor substrate made of a semiconductor material, or may be a semiconductor substrate in which a semiconductor layer is formed on a base substrate. For example, the first substrate 210 may be composed of monocrystalline or polycrystalline silicon, epitaxial silicon, germanium, silicon-germanium, silicon-on-insulator, or germanium-on-insulator.

The circuit elements 220 formed on the first substrate 210 may include various circuit components that control the operation of the memory cell structure provided in the cell region 100. For example, the circuit element 220 may configure a peripheral circuit structure such as a decoder circuit (a reference numeral 1110 of FIG. 18), a page buffer (a reference numeral 1120 of FIG. 18), and a logic circuit (a reference numeral 1130 of FIG. 18).

The circuit element 220 may include, for example, a plurality of transistors, but is not limited thereto. The circuit element 220 may include not only active elements such as transistors, but also passive elements such as capacitors, resistors, and inductors.

A circuit wire part 280 positioned on the first substrate 210 may be electrically connected to a circuit element 220. In some implementations, the circuit wire part 280 may include a plurality of wiring layers 286 spaced apart with an insulation layers 282 and connected to form a desired path by contact vias 284. The wiring layer 286 or the contact via 284 may include various conductive materials, and the insulation layer 282 may include various insulating materials. For example, the insulation layer 282 may include at least one of silicon oxide, silicon nitride, and silicon oxynitride.

The cell region 100 may include a cell array region 102 and a connection region 104. A gate stacking structure 120 and a channel structure CH may be formed on the second substrate 110 in the cell array region 102. A structure for connecting the gate stacking structure 120 and/or the channel structure CH formed in the cell array region 102 to the circuit region 200 or an external circuit may be positioned in the cell array region 102 and/or the connection region 104.

In some implementations, the second substrate 110 may include a semiconductor layer including a semiconductor material. For example, the second substrate 110 may be a semiconductor substrate made of a semiconductor material, and a semiconductor layer may be formed on the base substrate. For example, the second substrate 110 may be composed of silicon, germanium, silicon-germanium, silicon-on-insulator (SOI), or germanium-on-insulator (GOI). Here, the semiconductor layer included in the second substrate 110 may be doped with p-type or n-type impurities. For example, the p-type impurities may include boron (B), gallium (Ga), etc., and the n-type impurities may include phosphorus (P), arsenic (As), etc. However, the implementation is not limited to the material of the second substrate 110, the conductivity type of the impurity doped in the semiconductor layer, or the material.

In the cell array region 102, a gate stacking structure 120 including interlayer insulating layers 132m and gate electrodes 130 alternately stacked on one surface (e.g., the upper surface) of the second substrate 110, and a channel structure CH extending in the thickness direction (the Z-axis direction of the drawing) of the semiconductor device through the gate stacking structure 120 may be formed. Here, the thickness direction of the semiconductor device may be a direction (e.g., a vertical direction) that intersects (e.g., perpendicular to) the second substrate 110.

In some implementations, the cell array region 102 may include horizontal conductive layers 112, 114 positioned between the second substrate 110 and the gate stacking structure 120, and electrically connecting (e.g., directly connecting) the channel structure CH and the second substrate 110. The horizontal conductive layer 112 and 114 may include a first horizontal conductive layer 112 and/or a second horizontal conductive layer 114 sequentially positioned on a second substrate 110. The first horizontal conductive layer 112 may function as a part of a common source line of the semiconductor device. For example, the first horizontal conductive layer 112 may function as a common source line with the second substrate 110.

The first and second horizontal conductive layers 112 and 114 may include a semiconductor material (e.g., a polycrystalline silicon). For example, the first horizontal conductive layer 112 may include a polycrystalline silicon layer including an impurity. The implementation is not limited thereto and the second horizontal conductive layer 114 may be composed of a different material (e.g., an insulating material) than the first horizontal conductive layer 112 or the second horizontal conductive layer 114 may not be provided.

On the second substrate 110 (for example, on the first and second horizontal conductive layers 112 and 114 formed on the second substrate 110), the gate stacking structure 120 in which the cell insulation layers 132 (e.g., the interlayer insulating layer 132m, the first upper insulation layer 132a, the second upper insulation layer 132b, the third upper insulation layer 132c) and the gate electrodes 130 are alternately stacked may be positioned.

The gate electrode 130 may include a variety of conductive materials. For example, the gate electrode 130 may include a metallic material such as tungsten (W), copper (Cu), aluminum (Al), polycrystalline silicon, a metal nitride (e.g., titanium nitride (TiN), tantalum nitride (TaN)), or a combination thereof. As shown in the enlarged view of FIG. 2, a part of a blocking layer 156 (e.g., a first blocking layer 156a) composed of an insulating material may be positioned on the outside of the gate electrode 130. The interlayer insulating layer 132m may include various insulating materials. For example, the interlayer insulating layer 132m may include silicon oxide, silicon nitride, silicon oxynitride, a low dielectric constant material having a lower permittivity than silicon oxide, or a combination thereof.

Referring to FIG. 2, in some implementations, the channel structure CH may include a channel layer 140 and a gate dielectric layer 150 positioned on the channel layer 140 between the gate electrode 130 and the channel layer 140. The channel structure CH may further include a core insulation layer 142 positioned within the channel layer 140, but as another example, the core insulation layer 142 may not be provided. The channel structure CH may further include a channel pad 144 arranged on the channel layer 140 and/or the gate dielectric layer 150. A gate dielectric layer 150 positioned between the gate electrode 130 and the channel layer 140 may include a tunneling layer 152, a charge storage layer 154, and a blocking layer 156 sequentially formed on the channel layer 140.

Each channel structure CH may form a memory cell string, and the plurality of channel structures CH may be arranged spaced apart from each other in a row and column on a plane. For example, the plurality of channel structures CH may be arranged in various shapes, such as a lattice shape or a zigzag shape, on a plane. The channel structure CH may have a columnar shape. For example, the channel structure CH may have a slanted side surface so that the width becomes narrower (or at least partially narrower) as it approaches the second substrate 110 according to an aspect ratio when viewed in a cross-section. However, the implementation is not limited to this, and the arrangement, the structure, the shape, etc. of the channel structure CH may be variously modified.

The channel layer 140 may include a semiconductor material, for example, polycrystalline silicon. The core insulation layer 142 may include various insulating materials. For example, the core insulation layer 142 may include silicon oxide, silicon nitride, silicon oxynitride, or a combination thereof.

The tunneling layer 152 may include an insulating material capable of charge tunneling (e.g., silicon oxide, silicon oxynitride, etc.). The charge storage layer 154 may be used as a data storage region, and the charge storage layer 154 may include polycrystalline silicon, silicon nitride, etc. The blocking layer 156 may include an insulating material that may prevent undesirable inflow of charge into the gate electrode 130. For example, the blocking layer 156 may include silicon oxide, silicon nitride, silicon oxynitride, a high dielectric constant material having a permittivity higher than silicon oxide or a combination thereof. In some implementations, the blocking layer 156 may include a first blocking layer 156a including a portion extending horizontally along the gate electrode 130, and a second blocking layer 156b extending vertically between the first blocking layer 156a and the charge storage layer 154.

However, the material, the stacking structure, etc. of the channel layer 140, the core insulation layer 142, and the gate dielectric layer 150 may be modified in various ways, and the implementation is not limited thereto.

The channel pad 144 may be arranged to cover the upper surface of the core insulation layer 142 and be electrically connected to the channel layer 140. The channel pad 144 may include a conductive material, for example, impurity-doped polycrystalline silicon, but is not limited thereto.

In the implementation, the gate stacking structure 120 may include a plurality of stacked portions that are sequentially stacked. According to this, the number of the stacked gate electrodes 130 may be increased, thereby increasing the number of the memory cells with a stable structure.

FIG. 1 illustrates an example of the gate stacking structure 120 or the plurality of stacked portions including first to third gate stacked portion 121, 122, and 123.

However, the implementation is not limited thereto, and the gate stacking structure 120 or the plurality of stacked portions may include two or more than four gate stacked portions.

The first gate stacked portion 121 may include a plurality of gate electrodes 130 (e.g., a plurality of first electrodes) and a plurality of interlayer insulating layers 132m that are alternately stacked, and the second gate stacked portion 122 may include a plurality of gate electrodes 130 (e.g., a plurality of first electrodes) and a plurality of interlayer insulating layers 132m that are alternately stacked. Also, the third gate stacked portion 123 may include a plurality of gate electrodes 130 (e.g., a plurality of second electrodes) and a plurality of interlayer insulating layers 132m that are alternately stacked with each other.

When the plurality of gate stacked portions (e.g., the first to third gate stacked portion 121, 122, and 123) are provided as described above, the channel structure CH may have a plurality of channel portions (e.g., first to third channel portions CH1, CH2, and CH3) that are connected to each other and penetrate the plurality of gate stacked portions (e.g., the first to third gate stacked portion 121, 122, and 123). Each of the plurality of channel portions (e.g., the first to third channel portions CH1, CH2, and CH3) may have inclined side surfaces such that their widths become narrower (or at least partially narrower) as they approach the second substrate 110 depending on the aspect ratio when viewed in the cross-section, and channel bent parts CP1 and CP2 may be provided due to the width difference at the boundaries of the plurality of channel portions (e.g., the first to third channel portions CH1, CH2, and CH3). As another example, the plurality of channel portions may have continuously sloped side surfaces without a channel bent part. FIG. 2 illustrates an example in which the gate dielectric layer 150, the channel layer 140, and the core insulation layer 142 of the plurality of channel portions extend from each other to form an integral structure. As another example, the gate dielectric layer 150, the channel layer 140, and the core insulation layer 142 of the plurality of channel portions may be formed separately from each other and electrically connected to each other, or a separate channel pad may be additionally provided at the boundary of the plurality of channel portions. In this way, an implementation is not limited to the form of the plurality of channel portions.

Referring to FIG. 2, in the semiconductor device according to the present implementation, the plurality of channel portions may include channel stepped parts CC1 and CC2 positioned between the first to third channel portions CH1, CH2, and CH3. That is, the first channel stepped part CC1 may be positioned between the first channel portions CH1 and the second channel portions CH2, and the second channel stepped part CC2 may be positioned between the second channel portions CH2 and the third channel portions CH3. The first channel stepped part C1 and the second channel stepped part CC2 may have inclined side surfaces so that their widths become narrower (or at least partially narrower) as they approach the second substrate 110. Referring to FIG. 1 and FIG. 2, the first channel stepped part C1 and the second channel stepped part CC2 may be formed within the first upper insulation layer 132a and the second upper insulation layer 132b, respectively. The first upper insulation layer 132a may be positioned on the first gate stacked portion 121, and the second upper insulation layer 132b may be positioned on the second gate stacked portion 122. At this time, the thickness of the upper insulation layers 132a and 132b may be greater than the thickness of the interlayer insulating layer 132m.

The first channel stepped part CC1 and the second channel stepped part CC2 may be positioned within the first upper insulation layer 132a and the second upper insulation layer 132b. Referring to FIG. 2, the channel bent part CP1 and the first channel stepped part CC1 may be positioned between the first channel portions CH1 and the second channel portions CH2. Similarly, the channel bent part CP2 and the second channel stepped part CC2 may be positioned between the second channel portions CH2 and the third channel portions CH3. Therefore, as shown in FIG. 2, two protruding portions P1 and C1 may be positioned between the first channel portions CH1 and the second channel portions CH2. Similarly, two protruding portions P2 and C2 may be positioned between the second channel portions CH2 and the third channel portions CH3. This will be explained separately later, but it is a structure derived by simultaneously forming a penetration portion in the cell array region 102 and the connection region 104.

In some implementations, the gate stacking structure 120 may be partitioned into multiple parts on a plane by an isolation structure 146 that extends in the thickness direction (the Z-axis direction of the drawing) of the semiconductor device and penetrates the gate stacking structure 120. Also, an upper isolation region 148 may be formed on the gate stacking structure 120. On a plane, the isolation structure 146 and/or the upper isolation region 148 may be provided in multiple numbers so as to extend in the elongation direction of the gate electrode 130 (the X-axis direction of the drawing) and be spaced apart from each other by a predetermined distance in the intersecting direction with the gate electrode 130 (the Y-axis direction of the drawing).

The isolation structure 146 or the upper isolation region 148 may be filled with various insulating materials. For example, the isolation structure 146 or the upper isolation region 148 may include an insulating material such as silicon oxide, silicon nitride, or silicon oxynitride. However, the implementation is not limited to this, and the structure, the shape, the material, etc. of the isolation structure 146 or the upper isolation region 148 may be modified in various ways.

A connection region 104 and a cell wire part 180 may be provided to connect the gate stacking structure 120 and the channel structure CH provided in the cell array region 102 to the circuit region 200 or an external circuit. The connection region 104 may be arranged around the cell array region 102, and a part of the cell wire part 180 may be positioned in the connection region 104.

Here, the cell wire part 180 may include all members that electrically connect the gate electrode 130, the channel structure CH, the horizontal conductive layer 112, and 114 and/or the second substrate 110 to the circuit region 200 or the external circuit. For example, the cell wire part 180 may include a bit line 182, a gate contact part 190, a source contact part 186, an input/output connection wire 188, and a contact via 180a and a connection wire 180b connected thereto, respectively.

Referring to FIG. 1, the gate contact part 190 may include a first to thirty-sixth gate contact parts connected to the first to thirty-sixth gate electrodes, respectively. However, only a part of the gate contact part is shown in FIG. 1. FIG. 1 illustrates 36 layers of the gate electrodes, but this is only an example, and the number of the gate electrodes 130 stacked may vary. The gate contact part 190 may be positioned in the same number as the gate electrode 130 and may be electrically connected to the gate electrode 130 positioned in each layer. The connection relationship between the specific gate electrode 130 and the gate contact part 190 is described separately later.

The bit line 182 can be extended in a cross direction (Y-axis direction of the drawing) that intersects the elongation direction (X-axis direction of the drawing) of gate electrode 130. The bit line 182 may be electrically connected to the channel structure CH, for example, the channel pad 144, through a contact via 180a, for example, a bit line contact via, which penetrates the interlayer insulating layer 132m.

In the implementation, the gate stacking structure 120 may be positioned together in the cell array region 102 and the connection region 104. For example, in the connection region 104, the extension lengths of the plurality of gate electrodes 130 may be substantially the same. Here, to be substantially the same includes a case where there is a difference within a process error (e.g., within 10%). In the connection region 104, the plurality of gate contact parts 190 may penetrate a portion of the gate stacking structure 120 and be electrically connected to the plurality of gate electrodes 130, respectively.

In this implementation, a part of the gate stacking structure 120 may not be provided with a part (e.g., a part having a step shape) where a part of the gate stacking structure 120 is removed for the electrical connection between the gate electrode 130 and the gate contact part 190. The connection structure of the plurality of gate contact part 190 and the plurality of gate electrode 130 is explained in more detail later.

In the connection region 104, the source contact part 186 may penetrate the cell insulation layer 132 and be electrically connected to the horizontal conductive layers 112 and 114 and/or the second substrate 110, and the input/output connection wire 188 may pass through the gate stacking structure 120 or be arranged on the outside of the gate stacking structure 120 and be electrically connected to a circuit wire part 280 of the circuit region 200. The cell insulation layer 132 may include an interlayer insulating layer 132m, a first upper insulation layer 132a, a second upper insulation layer 132b, a third upper insulation layer 132c, and an insulation layer formed over and/or around the gate stacking structure 120.

FIG. 1 illustrates an example in which the source contact part 186 and/or the input/output connection wire 188 have the slanted side surfaces that, when viewed in cross-section, become narrower as they approach the second substrate 110 according to the aspect ratio, and have the bent parts at the boundaries of the plurality of gate stacked portions. However, the implementation is not limited thereto. It is also possible for the source contact part 186 and/or the input/output connection wire 188 not to have the bent part at the boundary of the plurality of gate stacked portions. Various other modifications are possible.

For clear understanding and simple illustration, FIG. 1 illustrates that the connection wire 180b is provided as a single layer positioned on the same plane as the bit line 182, and a separate insulation layer 180c is positioned on a part other than the connection wire 180b. However, the implementation is not limited thereto. Therefore, the connection wire 180b may include a plurality of wiring layers for the electrical connection with the bit line 182, the gate contact part 190, the source contact part 186 and/or the input/output connection wire 188, and may further include contact vias.

The cell wire part 180 may be electrically connected to the circuit wire part 280, so that the bit line 182, the gate electrode 130, the horizontal conductive layer 112 and 114 and/or the second substrate 110 electrically connected to the channel structure CH may be electrically connected to the circuit element 220 of the circuit region 200.

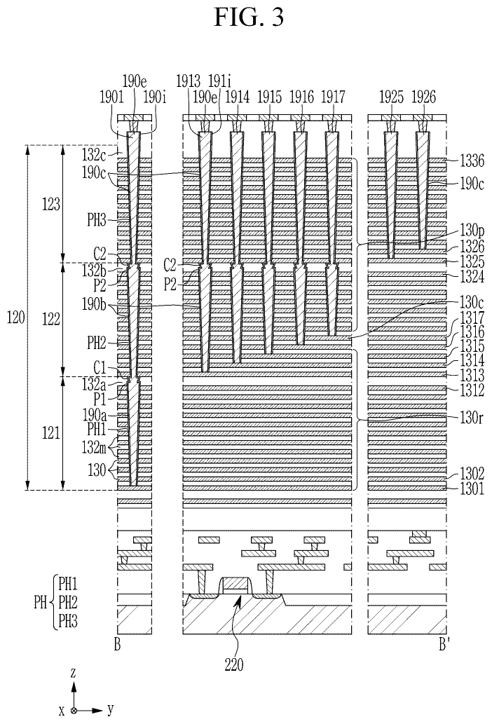

The connection structure of the plurality of gate contact parts 190 and the plurality of gate electrodes 130 are described with reference to FIG. 3 to FIG. 7 along with FIG. 1.

FIG. 3 is a cross-sectional view illustrating a connection region 104 of the cell region 100 included in the semiconductor device illustrated in FIG. 1. FIG. 3 illustrates the connection region 104 of the cell region 100 positioned at the B-B′ portion of FIG. 1. FIG. 3 illustrates that the gate electrode 130 includes the first to thirty-sixth gate electrodes 1301 to 1336, but this is only an example and the present invention is not limited thereto.

FIG. 3 mainly shows a first gate contact part 1901 electrically connected to the first gate electrode 1301, thirteenth to seventeenth gate contact parts 1913 to 1917 electrically connected to the thirteenth to seventeenth gate electrodes 1313 to 1317, respectively, and twenty-fifth and twenty-sixth gate contact parts 1925 and 1926 electrically connected to the twenty-fifth and twenty-sixth electrodes. Although not shown, the first to thirty-sixth gate electrodes 1301 to 1336 may be connected to the first to thirty-sixth gate contact parts 1901 to 1936, respectively.

Referring to FIG. 1 and FIG. 3, in the implementation, the plurality of gate contact parts 190 in the connection region 104 may penetrate a portion of the gate stacking structure 120 and be electrically connected (e.g., in contact with) to the plurality of gate electrodes 130, respectively.

For example, each gate contact part 190 may extend downward from the upper surface of the gate stacking structure 120 toward the bottom surface, thereby penetrating a portion of the gate stacking structure 120 in the thickness direction (the Z-axis direction of the drawing) of the semiconductor device. Here, the thickness direction of the semiconductor device may be a direction (e.g., a vertical direction) that intersects (e.g., perpendicular to) the second substrate 110. The upper surface of the gate stacking structure 120 may mean a surface positioned toward the cell wire part 180 in the thickness direction of the semiconductor device or a surface opposite to the second substrate 110, and the bottom surface of the gate stacking structure 120 may mean a surface opposite to the cell wire part 180 in the thickness direction of the semiconductor device or a surface positioned toward the second substrate 110. Unless otherwise specified, with respect to the cell region 100, the upper part or the upper surface may mean a part or a surface positioned toward cell wire part 180 or a part or surface opposite to second substrate 110, and the lower part or the bottom surface may mean a part or a surface opposite to cell wire part 180 or a part or a surface positioned toward the second substrate 110.

The plurality of gate contact parts 190 may be provided so as to be respectively connected to the plurality of gate electrodes 130. Since the plurality of gate electrodes 130 are positioned at the different heights in the thickness direction (the Z-axis direction of the drawing) of the semiconductor device, the plurality of gate contact parts 190 may have the different lengths or depths so that they may each reach the plurality of gate electrodes 130.

Each gate contact part 190 may penetrate a portion of the gate stacking structure 120 such that it has a depth that may reach the connection gate electrode 130c among the plurality of gate electrodes 130. For example, the first gate contact part may be electrically connected to the first gate electrode. Also, the n-th gate contact part may be electrically connected to the n-th gate electrode, and the k-th gate contact part may be connected to the kth gate electrode. Here, n may be a natural number greater than 1 and less than k, and k may correspond to the total number of the plurality of gate electrodes 130 or the total number of the plurality of gate contact parts 190.

The drawing illustrates the gate electrode 130 including the first to thirty-sixth gate electrodes. In this case, the first to twelfth gate contact parts may be electrically connected to the first to twelfth gate electrodes, the thirteenth to twenty-fourth gate contact part may be electrically connected to the thirteenth to twenty-fourth gate electrodes, respectively, and the twenty-fifth to thirty-sixth gate contact parts may be electrically connected to the twenty-fifth to thirty-sixth gate electrodes, respectively. In this way, the plurality of gate contact parts 190 may be electrically connected to the plurality of gate electrodes 130, respectively.

For the sake of clear understanding and simple illustration, the drawing shows that the depth of the plurality of gate contact parts 190 is arranged to sequentially increase as they get closer to the cell array region 102, but the implementation is not limited thereto. The arrangement of the plurality of gate contact part 190 may be varied in various ways.

Taking one gate contact part 190 as a reference, the plurality of gate electrodes 130 may include a connection gate electrode 130c electrically connected to one gate contact part 190, and may include a penetration gate electrode 130p and/or a remaining gate electrode 130r. The penetration gate electrode 130p may correspond to a gate electrode 130 positioned on the connection gate electrode 130c, as a gate electrode 130 that is penetrated by the gate contact part 190 but is electrically insulated from the gate contact part 190 by the side insulation layer 190i of the gate contact part 190. The remaining gate electrode 130r may correspond to a gate electrode 130 positioned under the connection gate electrode 130c, as a gate electrode 130 that is not penetrated by the gate contact part 190 and is electrically insulated from the gate contact part 190.

In the first gate contact part, the first gate electrode 1301 may correspond to the connection gate electrode 130c, and the gate electrode 130 positioned above the connection gate electrode 130c may correspond to the penetration gate electrode 130p. In the n-th gate contact part, the n-th gate electrode may correspond to the connection gate electrode 130c, the gate electrode 130 positioned on the connection gate electrode 130c may correspond to the penetration gate electrode 130p, and the gate electrode 130 positioned under the connection gate electrode 130c may correspond to the remaining gate electrode 130r.

For clear understanding, FIG. 3 shows the connection gate electrode 130c, the penetration gate electrode 130p, and the remaining gate electrode 130r with the seventeenth gate contact part 1917 as a reference.

In the implementation, each gate contact part 190 may be electrically connected (e.g., in contact with) to the upper surface of the connection gate electrode 130c. However, the implementation is not limited thereto. Each gate contact part 190 may be electrically connected (e.g., in contact with) to the other part (e.g., the side) of the connection gate electrode 130c.

In the implementation, each gate contact part 190 may include a conductive portion 190e and a side insulation layer 190i positioned between the conductive portion 190e and the gate stacking structure 120.

In each gate contact part 190, the side insulation layer 190i may be positioned between the side of at least the conductive portion 190e and the side of the penetration gate electrode 130p so as to electrically insulate the conductive portion 190e and the penetration gate electrode 130p. Also, the side insulation layer 190i may not be positioned on the bottom surface of the conductive portion 190e and/or the upper surface of the connection gate electrode 130c. That is, the side insulation layer 190i may not be positioned between the upper surface of the connection gate electrode 130c and the bottom surface of the gate contact part 190. For example, the bottom surface of the side insulation layer 190i may be in contact with the connection gate electrode 130c, or may be positioned between the upper surface and the bottom surface of the interlayer insulating layer 132m positioned on the connection gate electrode 130c.

According to this, the side insulation layer 190i may surround the entire side of the gate contact part 190 corresponding to the penetration gate electrode 130p, and may stably insulate between the gate contact part 190 and the penetration gate electrode 130p. However, the implementation is not limited to this, and the position of the side insulation layer 190i, the connection position of the gate contact part 190 and the connection gate electrode 130c, etc. may be modified in various ways.

For example, the conductive portion 190e has a column shape (for example, a column shape having a planar shape such as a circle, a polygon, or an ellipse), and the side insulation layer 190i may have various planar shapes, such as a cyclic (annular) shape, a ring shape, and a frame shape, surrounding the conductive portion 190e.

In the implementation, the gate contact part 190, each positioned inside the gate penetration portion PH, may be electrically connected to the upper portion of the connection gate electrode 130c. For example, a plurality of gate penetration portions PH individually penetrating the gate stacking structure 120 and spaced apart with the gate stacking structure 120 interposed therebetween may be included, one gate contact part 190 may be positioned in one gate penetration portion PH, and the bottom surface of the conductive portion 190e of the gate contact part 190 positioned inside the gate penetration portion PH may be positioned (e.g., in contact with) on the upper surface of the connection gate electrode 130c. For example, the plurality of gate contact parts 190 may be positioned within the plurality of gate penetration portions PH that are spaced apart from each other so as to have one-to-one correspondence with the plurality of gate contact parts 190. In the implementation, the gate penetration portion PH may have various planar shapes such as a circle, a polygon, an ellipse, etc., and the implementation is not limited to the planar shape of the gate penetration portion PH.

Accordingly, a pad region through which the plurality of gate contact parts 190 pass together (e.g., a pad insulation layer), or a portion (e.g., a portion having a step shape) of the gate stacking structure 120 removed for the electrical connection of the gate contact parts 190 may not be provided. That is, the plurality of gate contact parts 190 may be individually electrically connected to the plurality of gate electrodes 130 without the pad region or the pad insulation layer. Accordingly, the process of electrically connecting the gate contact part 190 and the gate electrode 130 may be simplified and the area of the connection region 104 may be reduced.

On the other hand, in a comparative example including the pad region, a process (e.g., a process for forming a part having a step shape) for etching a part of the gate stacking structure, a process for forming a pad insulation layer covering the step shape of the gate stacking structure, and a process for electrically connecting a plurality of gate contact parts penetrating one pad insulation layer to a plurality of gate electrodes must be performed. Accordingly, the process of forming the pad region and the process of forming the gate contact part may be complicated. In order to prevent the misalignment of the gate contact part in the pad region or pad insulation layer through which the plurality of gate contact parts penetrate together, a sufficient width must be secured between the plurality of gate contact parts. Accordingly, the area of the connection region may increase. However, the present implementation does not include a separate pad region, which may prevent these problems.

Referring to FIG. 3, each gate contact part 190 may have the plurality of connection parts (e.g., the first to third connection portions 190a, 190b, and 190c) that respectively penetrate through the plurality of gate stacked portions (e.g., the first to third gate stacked portions 121, 122, and 123) and are connected to each other. Each of the plurality of connection parts (e.g., the first to third connection portions 190a, 190b, and 190c) has an inclined side surface so that the width thereof becomes narrower (or at least partially narrower) as it approaches the second substrate 110 according to an aspect ratio when viewed in a cross-section, and bent parts P1 and P2 due to the width difference may be provided at the boundary of the plurality of connection parts (e.g., the first to third connection portions 190a, 190b, and 190c).

Referring to FIG. 3, in the semiconductor device according to the present implementation, the plurality of connection parts of each gate contact part 190 may include stepped parts C1 and C2 positioned between the first to third portions 190a, 190b, and 190c. That is, the first stepped part C1 may be positioned between the first connection portion 190a and the second connection portion 190b, and the second stepped part C2 may be positioned between the second connection portion 190b and the third connection portion 190c.

The first stepped part C1 and the second stepped part C2 may have inclined side surfaces so that the widths thereof become narrower (or at least partially narrower) as they approach the second substrate 110. Referring to FIG. 3, the first stepped part C1 and the second stepped part C2 may be formed within the first upper insulation layer 132a and the second upper insulation layer 132b, respectively. As previously described, the first upper insulation layer 132a and the second upper insulation layer 132b may have a thickness thicker than the interlayer insulating layer 132m.

The first stepped part C1 may be positioned within the first upper insulation layer 132a, and the second stepped part C2 may be positioned within the second upper insulation layer 132b. Referring to FIG. 3, the bent part P1 and the first stepped part C1 may be positioned between the first connection portion 190a and the second connection portion 190b. Likewise, the bent part P2 and the second stepped part C2 may be positioned between the second connection portion 190b and the third connection portion 190c. Therefore, as shown in FIG. 3, two protruding portions P1 and C1 may be positioned between the first connection portion 190a and the second connection portion 190b. Similarly, two protruding portions P2 and C2 may be positioned between the second connection portion 190b and the third connection portion 190c. This will be explained separately later, but it is a structure derived from the manufacturing process.

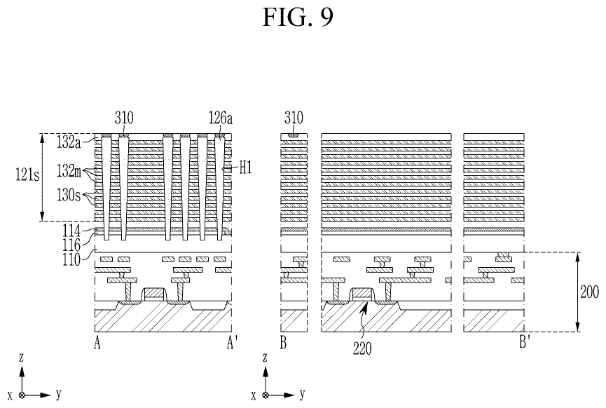

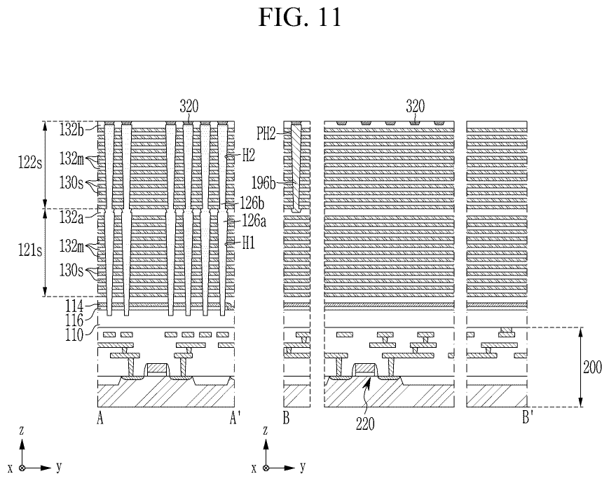

The first stepped part C1 and the second stepped part C2 are the regions where the etching stop pattern (referring to FIG. 9 and FIGS. 11, 310, 320) was positioned during the manufacturing process. The widths of the upper surfaces (the surfaces positioned away from the second substrate 110, the same hereinafter) of the first stepped part C1 and the second stepped part C2 may be the same as or similar to the widths of the upper surfaces of the first to third gate penetration portions PH1, PH2, and PH3, and the widths of the lower surfaces (the surfaces positioned close to the second substrate 110) of the first stepped part C1 and the second stepped part C2 may be narrower than the widths of the upper surfaces of the first to third gate penetration portions PH1, PH2, and PH3. Therefore, a step may be formed between the first stepped part C1 and the bent part P1, and a step may be formed between the second stepped part C2 and the bent part P2.

In the manufacturing process, since the etching stop pattern is formed within the first upper insulation layer 132a and the second upper insulation layer 132b, the first stepped part C1 and the second stepped part C2 may also be formed within the first upper insulation layer 132a and the second upper insulation layer 132b.

That is, as shown in FIG. 3, the width of each gate contact part may vary discontinuously. The stepped part and the bent part shown in FIG. 3 are parts where the width of the gate contact part changes discontinuously. Referring to FIG. 3, the widths are different at the boundary between the second connection portion 190b and the first stepped part C1. That is, the second connection portion 190b becomes narrower as it approaches the substrate and then increases at the boundary with the first stepped part C1 in the width. At this time, the width of the upper surface of the first stepped part C1 is wider than the lower surface of the second connection portion 190b, so the width of the gate contact part increases discontinuously. Similarly, at the boundary between the first stepped part C1 and the first connection portion 190a, the width of the first connection portion 190a may vary discontinuously. The first connection portion 190a increases in the width as it moves away from the substrate, and then narrows at the boundary with the first stepped part C1. At this time, the width of the lower surface of the first stepped part C1 is narrower than the upper surface of the first connection portion 190b, so the width of the gate contact part varies discontinuously.

That is, the fact that the width of the gate contact part varies discontinuously in this specification means that the inner side of the gate contact part includes a bent part (the stepped part, the bent part). Although this specification illustrates the configuration in which the misalignment does not occur at the boundaries of the first to third connection portions 190a, 190b, and 190c, it may also include a case in which the misalignment occurs at the boundaries of the first to third connection portions 190a, 190b, and 190c.

Additionally, the meaning that the width of the gate contact part varies discontinuously in the present specification includes configurations in which the width variations within the first to third connection portions 190a, 190b, and 190c, as shown in FIG. 3, and the width variations within the stepped parts C1 and C2 are different. That is, an imaginary straight line extending along the inner sides of the first to third connection portions 190a, 190b, and 190c and an imaginary straight line extending along the inner sides of the stepped parts C1 and C2 may not be parallel to each other.

In this way, a configuration in which the width change within the first to third connection portion 190a, 190b, and 190c and the width change within the stepped parts C1 and C2 are different is also included in a configuration in which the width of the gate contact part discontinuously changes.

Referring to FIG. 3, the number of the stepped parts included in the gate contact part 190 positioned at each of the gate stacked portion 121, 122, and 123 may be different.

Referring to FIG. 3, the gate contact part 190 connected to the gate electrode 130 positioned at the first gate stacked portion 121 may include a first stepped part C1 and a stepped part C2.

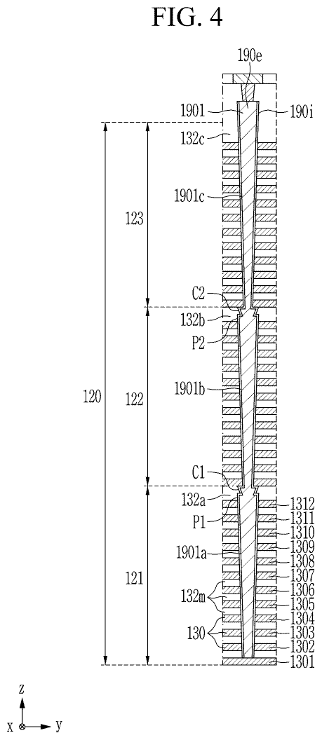

FIG. 4 illustrates the first gate contact part 1901 connected to the first gate electrode 1301 among the gate contact part 190 connected to the gate electrode 130 positioned at the first gate stacked portion 121. Referring to FIG. 4, the first gate contact part 1901 may include a first stepped part C1 and a second stepped part C2, and the first gate contact part 1901 may include bent parts P1 and P2 positioned at the boundaries of the first to third connection portion 190a, 190b, and 190c.

Therefore, as shown in FIG. 4, the first gate contact part 1901 may include two protruding portions P1 and C1, positioned between the first connection portion 1901a and the second connection portion 1901b. Two protruding portions P1 and C1 may both be positioned within the first upper insulation layer 132a. Similarly, the first gate contact part 1901 may include two protruding portions P2, and C2 positioned between the second connection portion 1901b and the third connection portion 1901c. Two protruding portions P2 and C2 may both be positioned within the second upper insulation layer 132b.

That is, the gate contact part 190 connected to the first gate stacked portion 121 may include four protruding portions P1, P2, C1, C2.

Although not shown in FIG. 4, the second to twelfth gate electrode 1302 to 1312 may be connected to the second to the twelfth gate contact part. The second to twelfth gate contact part may also include two protruding portions C1, and P1 positioned in the first upper insulation layer 132a, and two protruding portions C2, and P2 positioned in the second upper insulation layer 132b.

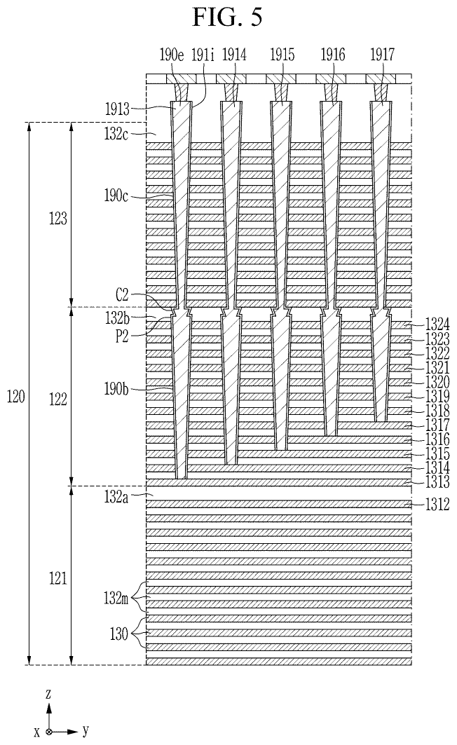

FIG. 5 illustrates thirteenth to seventeenth gate contact parts 1913 to 1917 connected to the gate electrode 130 positioned on the second gate stacked portion 122. Referring to FIG. 5, the gate contact part 190 connected to the gate electrode 130 positioned at the second gate stacked portion 122 may include a second stepped part C2. Additionally, the gate contact part 190 positioned at the second gate stacked portion 122 may include a second connection portion 190b and a third connection portion 190c, and may include a bent part P2 positioned at the boundary between the second connection portion 190b and the third connection portion 190c. That is, the gate contact part 190 positioned at the second gate stacked portion 122 may include two protruding portions C2 and P2 between the second connection portion 190b and the third connection portion 190c. Comparing FIG. 4 and FIG. 5, the gate contact part 190 connected to the first gate stacked portion 121 may include four protruding portions P1, P2, C1, and C2, and the gate contact part 190 connected to the second gate stacked portion 122 may include two protruding portions P2 and S2.

Referring to FIG. 5, the thirteenth gate contact part 1913 may be connected to the thirteenth gate electrode 1313, the fourteenth gate contact part 1914 may be connected to the fourteenth gate electrode 1314, the fifteenth gate contact part 1915 may be connected to the fifteenth gate electrode 1315, and the sixteenth gate contact part 1916 may be connected to the sixteenth gate electrode 1316, and the seventeenth gate contact part 1917 may be connected to the seventeenth gate electrode 1317. Although not shown, the eighteenth to twenty-fourth gate electrodes 1318 to 1324 may be connected to the eighteenth to twenty-fourth gate contact parts.

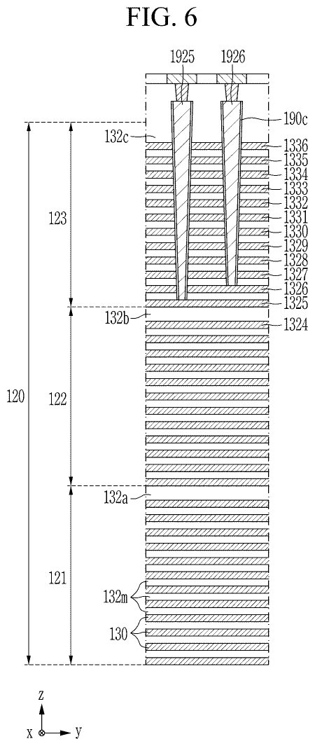

FIG. 6 illustrates a twenty-fifth to twenty-sixth gate contact parts 1925 to 1926 connected to the gate electrode 130 positioned at the third gate stacked portion 123. Referring to FIG. 6, the gate contact part 190 positioned at the third gate stacked portion 123 may not include a bent part or a stepped part. That is, the gate contact part 190 connected to the third gate stacked portion 123 includes the third connection portion 190c, and does not include the first connection portion 190a and the second connection portion 190b. Therefore, the gate contact part 190 connected to the third gate stacked portion 123 may not include a stepped part or a bent part. Referring to FIG. 6, the twenty-fifth gate contact part 1925 may be connected to the twenty-fifth gate electrode 1325, and the twenty-sixth gate contact part 1926 may be connected to the twenty-sixth gate electrode 1326. Although not shown, the twenty-seventh to thirty-sixth gate electrodes 1327 to 1336 may be connected to the twenty-seventh to thirty-sixth gate contact parts.

As described above, the semiconductor device according to the present implementation may include two protruding portions P1 and C1a where the gate contact part 190 is positioned between the first gate stacked portion 121 and the second gate stacked portion 122, and two protruding portions P2 and C2 positioned between the second gate stacked portion 122 and the third gate stacked portion 123. Specifically, the bent part P1 and the first stepped part C1 may be positioned in the first upper insulation layer 132a, and the bent part P2 and the second stepped part C2 may be positioned in the second upper insulation layer 132b.

When the gate contact part 190 is formed with the length that penetrates the first upper insulation layer 132a and the second upper insulation layer 132b, it may include four protruding portions P1, P2, C1, and C2, and when the gate contact part 190 is formed with the length that penetrates the second upper insulation layer 132b without penetrating the first upper insulation layer 132a, it may include two protruding portions P2 and C2. Additionally, if the gate contact part 190 is formed with the length that does not penetrate the first upper insulation layer 132a and the second upper insulation layer 132b, the protruding portion may not be included.

As will be explained separately later, the stepped parts C1 and C2 may be structures derived from a process for simultaneously forming the channel penetration portion for forming the channel CH of the cell array region 102 and the gate penetration portion for forming a gate contact part 190 of the connection region 104.

In the previous implementation, the channel CH is disclosed as including the channel stepped parts CC1 and CC2 positioned between the plurality of channel portions CH1, CH2, and CH3, but in another implementation, the channel CH may not include the channel stepped parts CC1 and C2 positioned between the plurality of channel portions CH1, CH2, and CH3. That is, the channel bent parts CP1 and CP2 may be positioned between the channel portions CH1, CH2, and CH3 and may not include the channel stepped parts CC1 and CC2.

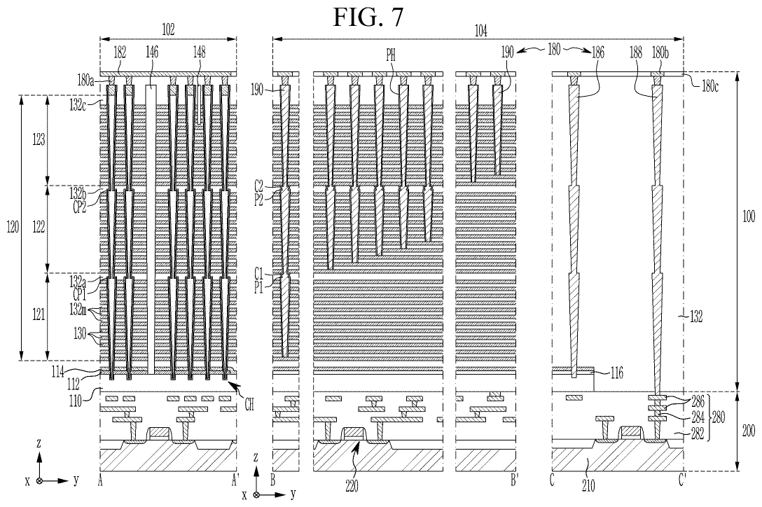

FIG. 7 illustrates the same region as FIG. 1 for another implementation. FIG. 7 is the same as the implementation of FIG. 1, except that the channel CH does not include the channel stepped part CC1, and CC2 between the plurality of channel portions CH1, CH2, and CH3. The specific descriptions of the same components are omitted. Referring to FIG. 7, the gate contact part 190 positioned in the connection region 104 may include bent parts P1 and P2 and stepped parts C1, and C2 positioned between the first gate stacked portion 121, the second gate stacked portion 122 and the third gate stacked portion 123, respectively. However, compared with FIG. 1, the channel CH positioned in the cell array region 102 may not include a channel stepped part positioned between the plurality of channel portions CH1, CH2, and CH3, but may include only channel bent parts CP1 and CP2. The stepped parts C1 and C2 and the channel stepped parts CC1 and CC2 are regions where an etching stop pattern was positioned to prevent the lower part from being etched during the manufacturing process. In the case of the channel portions CH1, CH2, and CH3, the etching prevention of the lower part is not an essential configuration, and thus, the formation of the etching stop pattern may be omitted when etching the channel portions CH1, CH2, and CH3 in the manufacturing process, and in this case, the channel CH may not include the channel stepped parts CC1 and CC2 between the plurality of channel portions CH1, CH2, and CH3.

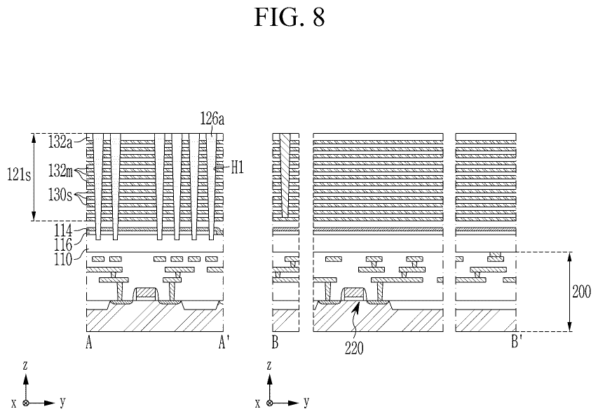

Hereinafter, the manufacturing method of the semiconductor device according to some implementations is described in more detail with reference to FIG. 8 to FIG. 17. For the parts that have already been explained, the detailed descriptions are omitted, and for parts that have not been explained, detailed descriptions are provided.

FIG. 8 to FIG. 17 are partial cross-sectional views illustrating a manufacturing method of a semiconductor device according to some implementations. FIG. 8 to FIG. 17 illustrate the cell array region and the connection region of the cell region positioned at the portion A-A′ and the portion B-B′ of FIG. 1. Below, the manufacturing method of the semiconductor device is explained mainly with regard to the gate stacking structure 120, the channel structure CH, the isolation structure 146, and the gate contact part 190.

As shown in FIG. 8, a second substrate 110 and a first sacrificial stacked portion 121s may be formed on the circuit region 200, and a first channel sacrificial portion 126a may be formed in the cell array region.

The first sacrificial stacked portion 121s may a part corresponding to the first gate stacked portion 121 of FIG. 1.

In further detail, the second substrate 110 may be formed on the circuit region 200, a horizontal insulation layer 116 and a second horizontal conductive layer 114 may be formed on the second substrate 110, and then a first sacrificial stacked portion 121s may be formed by alternately stacking an interlayer insulating layer 132m and a sacrificial insulation layer 130s. For example, the first sacrificial stacked portion 121s may be formed in the cell array region and the connection region and may include a plurality of sacrificial insulation layers 130s and a plurality of interlayer insulating layers 132m which are alternately included in each other. A first upper insulation layer 132a may be positioned on the first sacrificial stacked portion 121s. The thickness of the first upper insulation layer 132a may be thicker than the thickness of the interlayer insulating layer 132m.

The sacrificial insulation layer 130s is a layer that is replaced with a gate electrode (a reference numeral 130 of FIG. 1, the same is applied hereinafter) through a subsequent process, and may be formed to correspond to a portion where a gate electrode 130 is to be formed. At least a portion of the horizontal insulation layer 116 may be formed as a layer that is replaced by a first horizontal conductive layer (a reference numeral 112 of FIG. 1, the same is applied hereinafter) through a subsequent process, such that it includes a portion where the first horizontal conductive layer 112 is to be formed.

The horizontal insulation layer 116 and/or the sacrificial insulation layer 130s may be formed of a material different from the interlayer insulating layer 132m. For example, the interlayer insulating layer 132m may include silicon oxide, silicon nitride, silicon oxynitride, a low dielectric constant material, etc., and the sacrificial insulation layer 130s may include at least one of silicon, silicon oxide, silicon carbide, and silicon nitride, and may be made of a material different from the interlayer insulating layer 132m.

Also, the first channel sacrificial portion 126a may be formed to penetrate the first sacrificial stacked portion 121s in the cell array region. In further detail, the first channel sacrificial portion 126a may be formed to penetrate the first sacrificial stacked portion 121s, the horizontal insulation layer 116, and the second horizontal conductive layer 114.

For example, a first channel penetration portion H1 may be formed penetrating the first sacrificial stacked portion 121s corresponding to a portion where the channel structure (a reference symbol CH of FIG. 1, the same is applied hereinafter) is to be formed, and a sacrificial material may be filled into the first channel penetration portion H1 to form the first channel sacrificial portion 126a.

The first channel penetration portion H1 may be formed by various processes (e.g., an etching process, etc.), and the process of filling the first channel penetration portion H1 with a sacrificial material may be performed by various processes (e.g., a deposition process, etc.). The first channel sacrificial portion 126a may include at least one of a metallic material or a non-metallic material, for example, polycrystalline silicon, tungsten, titanium nitride, and carbon. However, the implementation is not limited thereto, and the first channel sacrificial portion 126a may include various materials.

Next, as shown in FIG. 9, a first upper insulation layer 132a is formed over the first channel penetration portion H1 of the cell array region 102 and the connection region 104. At this step, the first upper insulation layer 132a may include the same material as the first upper insulation layer 132a formed at the previous step, and the boundary with the first upper insulation layer 132a formed at the previous step may not be visible. Afterwards, a first etching stop pattern 310 is formed within the first upper insulation layer 132a. The first etching stop pattern 310 may include TIN, but is not limited thereto.

The first etching stop pattern 310 may be formed by overlapping the first channel penetration portion H1 of the cell array region 102 and may also be formed on the connection region 104. As will be explained separately later, the first etching stop pattern 310 may be formed in the region where a gate penetration portion will be formed later in the connection region 104.

The first etching stop pattern 310 may function as an etch stop layer to prevent the first sacrificial stacked portion 121s from being etched during the formation of the gate penetration portion of the subsequent process. As shown in FIG. 9, the first etching stop pattern 310 may have a sloped sidewall that become narrower as they approach the second substrate 110. The first etching stop pattern 310 may be formed within the first upper insulation layer 132a. The width of the upper surface of the first etching stop pattern 310 may be the same as or similar to the width of the upper surface of the first channel penetration portion H1, and the width of the lower surface of the first etching stop pattern 310 may be narrower than the width of the upper surface of the first channel penetration portion H1. The first etching stop pattern 310 may be formed to be in contact with the first channel penetration portion H1.

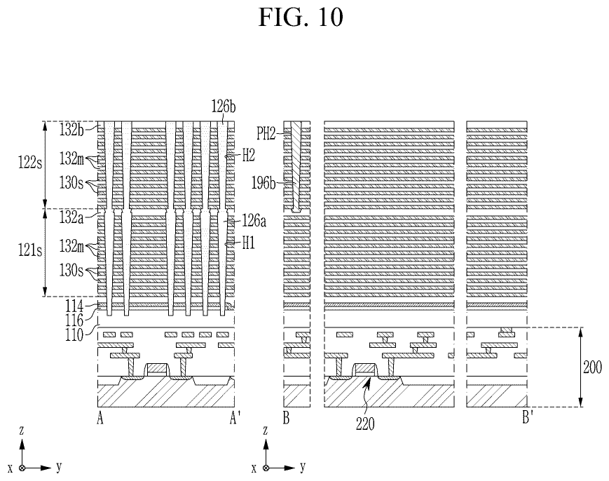

Next, referring to FIG. 10, a second sacrificial stacked portion 122s may be formed on the first sacrificial stacked portion 121s.

The second sacrificial stacked portion 122s may a portion of corresponding to the second gate stacked portion 122 of FIG. 1. The second sacrificial stacked portion 122s may be formed by the same process as the first sacrificial stacked portion 121s. The specific descriptions of the same components are omitted. Referring to FIG. 10, the interlayer insulating layer 132m and the sacrificial insulation layer 130s may be alternately stacked to form the second sacrificial stacked portion 122s. For example, the second sacrificial stacked portion 122s may be formed in the cell array region and the connection region and may include a plurality of sacrificial insulation layers 130s and a plurality of interlayer insulating layers 132m which are alternately included in each other. The second upper insulation layer 132b may be positioned on the first sacrificial stacked portion 121s. The thickness of the second upper insulation layer 132b may be thicker than the thickness of the interlayer insulating layer 132m.

Next, a second channel penetration portion H2 may be formed penetrating the second sacrificial stacked portion 122s in the cell array region 102, and a sacrificial material may be filled into the second channel penetration portion H2 to form a second channel sacrificial portion 126b. At this time, the second channel penetration portion H2 may be formed to overlap the first channel penetration portion H1 formed in the previous step in the third direction (the z direction). The second channel sacrificial portion 126b formed in the present step may be connected as one with the first channel sacrificial portion 126a formed in the previous step.

Specifically, a second channel penetration portion H2 that penetrates the second sacrificial stacked portion 122s corresponding to the portion where the channel structure (a reference symbol CH of FIG. 1, the same applies hereinafter) is to be formed may be formed. Next, the first etching stop pattern 310 formed in the previous step through the second channel penetration portion H2 may be removed. Next, a sacrificial material may be filled into the portion from which the first etching stop pattern 310 has been removed and the second channel penetration portion H2 to form the second channel sacrificial portion 126b.

The second channel penetration portion H2 may be formed by various processes (e.g., an etching process, etc.), and the process of filling the second channel penetration portion H2 with the sacrificial material may be performed by various processes (e.g., a deposition process, etc.). The second channel sacrificial portion 126b may include at least one of a metallic material or a non-metallic material, for example, polycrystalline silicon, tungsten, titanium nitride, and carbon. However, the implementation is not limited thereto, and the second channel sacrificial portion 126b may include various materials.

At this time, the second gate penetration portion PH2 may be formed in the connection region 104 by the same process as the forming process of the second channel penetration portion H2. At this time, the second gate penetration portion PH2 may be formed by penetrating the second sacrificial stacked portion 122s, and may be formed using the first etching stop pattern 310 as an etch stop layer. That is, the second gate penetration portion PH2 may be formed up to the upper portion of the first etching stop pattern 310. The second gate penetration portion PH2 may have the sloped side surface so that the width thereof becomes narrower (or at least partially narrower) as it approaches the second substrate 110. Next, the first etching stop pattern 310 may be removed through the second gate penetration portion PH2, and a sacrificial material may be filled in the region where the first etching stop pattern 310 was removed and the second gate penetration portion PH2 to form the second sacrificial gate contact portion 196b. At this time, the sacrificial material filled in the second gate penetration portion PH2 may be the same material as the sacrificial material filled in the second channel penetration portion H2.

In FIG. 10, only one second gate penetration portion PH2 is illustrated for convenience of the illustration, but the number of the second gate penetration portions PH2 formed at the present step may be equal to the number of the sacrificial insulation layer 130s positioned at the first sacrificial stacked portion 121s. That is, each second gate penetration portion PH2 may be connected to each gate electrode 130 positioned at the first gate stacked portions (a reference numeral 121 of FIG. 1) through a process of a subsequent step.

Next, referring to FIG. 11, a second upper insulation layer 132b is formed on the second channel penetration portion H2 of the cell array region 102 and the connection region 104. At the present step, the second upper insulation layer 132b may include the same material as the second upper insulation layer 132b formed at the previous step, and therefore, the boundary with the second upper insulation layer 132b formed at the previous step may not be recognized. Afterwards, a second etching stop pattern 320 is formed within the second upper insulation layer 132b. The second etching stop pattern 310 may include TIN, but is not limited thereto.

The second etching stop pattern 320 may be formed by overlapping the second channel penetration portion H2 of the cell array region 102 and may also be formed on the connection region 104. As will be explained separately later, a second etching stop pattern 320 may be formed in the region where the gate penetration portion will be formed later in the connection region 104.

The second etching stop pattern 320 may function as an etch stop layer that prevents the second sacrificial stacked portion 122s from being etched during the formation process of the gate penetration portion of the subsequent process. As shown in FIG. 11, the second etching stop pattern 320 may have an angled side surfaces so that the width becomes narrower (or at least partially narrower) closer to the second substrate 110. The second etching stop pattern 320 may be formed within the second upper insulation layer 132b. The width of the upper surface of the second etching stop pattern 320 may be the same as or similar to the width of the upper surface of the second channel penetration portion H2, and the width of the lower surface of the second etching stop pattern 320 may be narrower than the width of the upper surface of the second channel penetration portion H2. The second etching stop pattern 320 may be formed to be in contact with the second channel penetration portion H2.

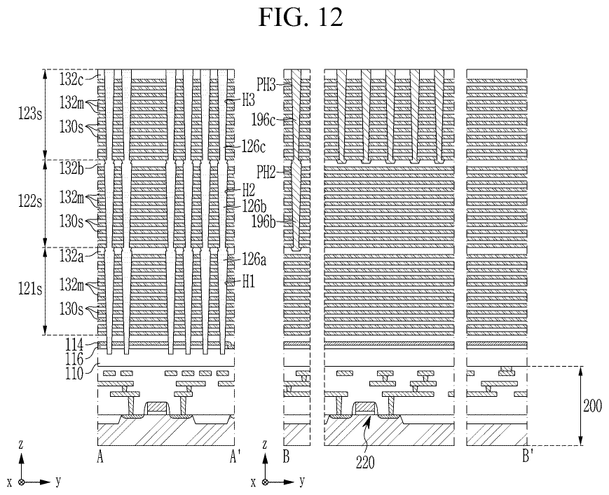

Next, referring to FIG. 12, a third sacrificial stacked portion 123s is formed on the second sacrificial stacked portion 122s. The third sacrificial stacked portion 123s may a portion corresponding to the third gate stacked portion 123 of FIG. 1. The third sacrificial stacked portion 123s may be formed by the same process as the first sacrificial stacked portion 121s and the second sacrificial stacked portion 122s. The specific descriptions of the same components are omitted. Referring to FIG. 12, the interlayer insulating layer 132m and the sacrificial insulation layer 130s may be alternately stacked to form a third sacrificial stacked portion 123s. For example, the third sacrificial stacked portion 123s may be formed in the cell array region 102 and the connection region 104 and may include a plurality of sacrificial insulation layers 130s and a plurality of interlayer insulating layers 132m which are alternately formed in each other. The third upper insulation layer 132c may be positioned on the third sacrificial stacked portion 123s.

Next, a third channel penetration portion H3 penetrating the third sacrificial stacked portion 123s in the cell array region 102 may be formed, and a sacrificial material may be filled into the third channel penetration portion H3 to form a third channel sacrificial portion 126c. At this time, the third channel penetration portion H3 may be formed to overlap the first channel penetration portion H1 and the second channel penetration portion H2 formed in the previous step in the third direction (the z direction). The third channel sacrificial portion 126c formed in the present step may be connected as one with the first channel sacrificial portion 126a and the second channel sacrificial portion 126b formed in the previous step.

Specifically, the third channel penetration portion H3 penetrating the third sacrificial stacked portion 123s may be formed corresponding to a portion where the channel structure (the reference symbol CH of FIG. 1, the same applies hereinafter) is to be formed. Next, the second etching stop pattern 320 formed in the previous step may be removed through the third channel penetration portion H3. Next, the sacrificial material may be filled into the portion where the second etching stop pattern 320 is removed and the third channel penetration portion H3 to form the third channel sacrificial portion 126c.

The third channel penetration portion H3 may be formed by various processes (e.g., an etching process, etc.), and the process of filling the third channel penetration portion H3 with the sacrificial material may be performed by various processes (e.g., a deposition process, etc.). The third channel sacrificial portion 126c may include at least one of a metallic material or a non-metallic material, for example, polycrystalline silicon, tungsten, titanium nitride, and carbon. However, the implementation is not limited thereto, and the third channel sacrificial portion 126c may include various materials.

At this time, the third gate penetration portion PH3 may be formed in the connection region 104 by the same process as the forming process of the third channel penetration portion H3. At this time, the third gate penetration portion PH3 may be formed by penetrating the third sacrificial stacked portion 123s, and may be formed using the second etching stop pattern 320 as an etch stop layer. That is, the third gate penetration portion PH3 may be formed up to the upper portion of the second etching stop pattern 320. The third gate penetration portion PH3 may have a sloped side surface so that its width becomes narrower (or at least partially narrower) as it approaches the second substrate 110. Next, the second etching stop pattern 320 may be removed through the third gate penetration portion PH3, and a sacrificial material may be filled in the region where the second etching stop pattern 320 was removed and the third gate penetration portion PH3 to form a third sacrificial gate contact portion 196c. At this time, the sacrificial material filled in the third gate penetration portion PH3 may be the same material as the sacrificial material filled in the third channel penetration portion H3.

In FIG. 12, only six third gate penetration portions PH3 are illustrated for convenience of the illustration, but the number of the third gate penetration portions PH3 formed at the present step may be equal to the number of the sacrificial insulation layers 130s positioned on the first sacrificial stacked portion 121s and the second sacrificial stacked portion 122s. That is, each third gate penetration portion PH3 may be connected to each gate electrode 130 positioned at the first gate stacked portion (the reference numeral 1211 of FIG. 1) and the second gate stacked portion (the reference numeral 122 of FIG. 1) through a process of a subsequent step.

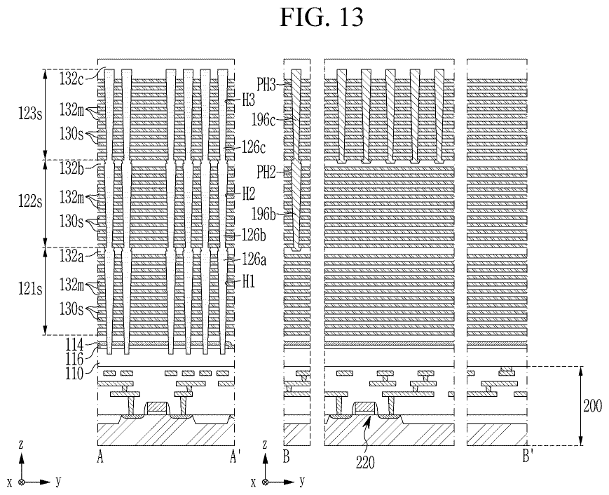

Next, referring to FIG. 13, a third upper insulation layer 132c is formed on the third sacrificial stacked portion 123s. The thickness of the third upper insulation layer 132c formed at the present step may be thicker than the thickness of the interlayer insulating layer 132m. At the present step, the upper part of the third channel penetration portion H3 and the upper part of the third gate penetration portion PH3 may be covered by the third upper insulation layer 132c.

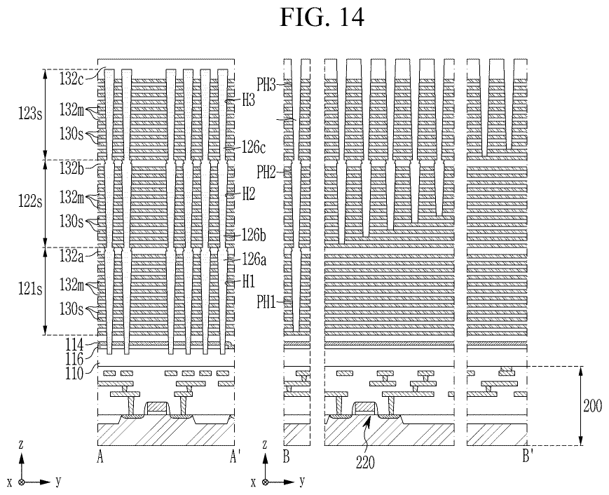

Next, referring to FIG. 14, the sacrificial material filling the second gate penetration portion PH2 and the third gate penetration portion PH3 formed in the previous step may be removed.

Next, a plurality of first gate penetration portions PH1 in contact with each sacrificial insulation layer 130s may be formed in the first sacrificial stacked portion 121s through the second gate penetration portion PH2 and the third gate penetration portion PH3. Through the same process, the second gate penetration portion PH2 in contact with each sacrificial insulation layer 130s may be formed in the second sacrificial stacked portion 122s through the third gate penetration portion PH3. In addition, the third gate penetration portion PH3 in contact with each sacrificial insulation layer 130s may be formed in the third sacrificial stacked portion 123s by using the same process. That is, the first gate penetration portion PH1, the second gate penetration portion PH2, and the third gate penetration portion PH3 formed in the present step may have the different lengths and be formed to come into contact with the sacrificial insulation layer 130s positioned in the different layers one by one. In this process, each sacrificial insulation layer 130s may come into contact with each gate penetration portion.

In the first sacrificial stacked portion 121s of FIG. 14, only one first gate penetration portion PH1 is illustrated for convenience of the illustration, but the number of the first gate penetration portion PH1 formed at the present step may be equal to the number of the sacrificial insulation layers 130s positioned on the first sacrificial stacked portion 121s. Each first gate penetration portion PH1 may then be formed up to the upper portion of each gate electrode 130 positioned at the first gate stacked portion (the reference numeral 121 of FIG. 1).

Also, referring to FIG. 14, the second gate penetration portion PH2 is formed through the third gate penetration portion PH3 in the second sacrificial stacked portion 122s. In FIG. 14, only the fifth second gate penetration portion PH2 are illustrated for convenience of the illustration, but the number of the second gate penetration portion PH2 formed at the present step may be equal to the number of the sacrificial insulation layer 130s positioned on the second sacrificial stacked portion 122s. Each second gate penetration portion PH2 may be formed over each sacrificial insulation layer 130s positioned on the second sacrificial stacked portion 122s. That is, each second gate penetration portion PH2 may be formed up to the upper portion of each gate electrode 130 positioned at the second gate stacked portion (the reference numeral 122 of FIG. 1).

In FIG. 14, only two third gate penetration portions PH3 are illustrated for convenience of the illustration, but the number of the third gate penetration portion PH3 formed at the present step may be equal to the number of the sacrificial insulation layer 130s positioned on the third sacrificial stacked portion 123s. Each third gate penetration portion PH3 may be formed over each sacrificial insulation layer 130s positioned on the third sacrificial stacked portion 123s. That is, each third gate penetration portion PH3 may be formed up to the upper portion of each gate electrode 130 positioned at the third gate stacked portions (the reference numeral 123 of FIG. 1).

That is, in FIG. 14, the gate penetration portion may be formed simultaneously in the first sacrificial stacked portion 121s, the second sacrificial stacked portion 122s, and the third sacrificial stacked portion 123s through the second gate penetration portion PH2 and the third gate penetration portion PH3 formed in the previous step. The plurality of gate penetration portion formed at this time may have the different lengths and may be formed to be in contact with the different sacrificial insulation layer 130s.

For this implementation, the process may be simplified compared to the process of forming the gate penetration portion in each of the first sacrificial stacked portion 121s, the second sacrificial stacked portion 122s, and the third sacrificial stacked portion 123s.

In FIG. 14, the process of simultaneously forming the gate penetration portions that are in contact with the different sacrificial insulation layers 130s in the first sacrificial stacked portion 121s, the second sacrificial stacked portion 122s, and the third sacrificial stacked portion 123s may use a plurality of partial etching processes using a binary method. That is, in the implementation, the position (a position or a level in the vertical direction) of the sacrificial insulation layer 130s to be replaced by the gate electrode 130 may be converted into a binary, and the plurality of partial etching processes (e.g., the first to fourth partial etching processes) may be performed correspondingly to form the gate penetration portions having the different depths.

The manufacturing method according to the present implementation simultaneously forms the part of the gate penetration portions PH1, PH2, and PH3 in the process of forming the channel penetration portions H1, H2, and H3. Therefore, compared to a manufacturing method in which the gate penetration portions PH1, PH2, and PH3 are not formed in advance, the plurality of partial etching processes using a binary method may be reduced.

The specific process reduction effect is explained using an example. For example, in the manufacturing method of the semiconductor device including 36 layers of the sacrificial insulation layer 130s, as shown in FIG. 1, in order to form the gate penetration portion positioned up to the upper part of the sacrificial insulation layer 130s positioned on each different layer by using the binary method, a process (a first partial etching process) for etching one layer of an interlayer insulating layer 132m, a process (second partial etching process) for etching two layers of an interlayer insulating layer 132m, a process(a third partial etching process) for etching four layers of an interlayer insulating layer 132m, a process (a fourth partial etching process) for etching eight layers of an interlayer insulating layer 132m, a process (a fifth partial etching process) for etching 16 layers of an interlayer insulating layer 132m, and a process (a sixth partial etching process) for etching 32 layers of an interlayer insulating layer 132m are required.

For better understanding and ease of the explanation, the etched depth is described as the number of the layers of the interlayer insulating layer 132m, but this is the depth including the sacrificial insulation layer 130s positioned between the interlayer insulating layers 132m.

The number 32, when is converted to a binary, is 100100, by etching the 36 layers through the sixth partial etching process (the 32-layer etching) and the third partial etching process (the 4-layer etching), the gate penetration portion in contact with the first gate electrode (the reference symbol 1301 in FIG. 1) may be formed. Using the binary as the same method, the plurality of gate penetration portions that are in contact with each gate electrode from the second gate electrode 1302 to the thirty-sixth gate electrode 1336 may be formed. In other words, the maximum number of the layers that should be etched in the present process is 36.

However, as in the present implementation, when forming a part of the gate penetration portions PH2 and PH3 simultaneously in the process of forming the channel penetration portions H1, H2, and H3, the maximum number of the layers that must be etched to form the gate penetration portion in contact with each gate electrode 130 is reduced to 12. This is because some layers have already been etched through the formation of the gate penetration portions PH2 and PH3 in the previous step. Therefore, the gate penetration portion positioned up to the upper part of the sacrificial insulation layer 130s respectively positioned at the different layer may be formed by the process (the first partial etching process) of etching one layer of the interlayer insulating layer 132m, the process (second partial etching process)of etching two layers of the interlayer insulating layer 132m, the process (the third partial etching process) of etching four layers of the interlayer insulating layer 132m, and the process(fourth partial etching process) of etching eight layers of the interlayer insulating layer 132m.

The number 12, when is converted to the binary, is 1100, by etching 12 layers through the fourth partial etching process (the 8-layer etching) and the third partial etching process (the 4-layer etching), the gate penetration portion that is in contact with the first gate electrode (the reference symbol 1301 in FIG. 1) may be formed. Using the same method of the binary, the plurality of gate penetration portions that are in contact with each gate electrode from the second gate electrode 1302 to the thirty-sixth gate electrode 1336 may be formed. For the first gate contact part 1911 in contact with the first gate electrode 1301, if the gate penetration portion PH2 and PH3 have not been etched in advance, the interlayer insulating layer 132m of the 36 layers must be etched. However, since the gate penetration portion PH2 and PH3 are formed through the etching process in the previous step, and the 24 layers have already been etched, the number of the layers to be etched is reduced to 12 layers. Therefore, the process may be simplified.

In the present implementation, for better comprehension and ease of the description, each sacrificial stacked portion includes the 12 layers of the interlayer insulating layer 132m, and the structure in which the 36 layers of the interlayer insulating layer 132m are positioned in the entire semiconductor device is explained as an example, but this is only an example and the present invention is not limited thereto.

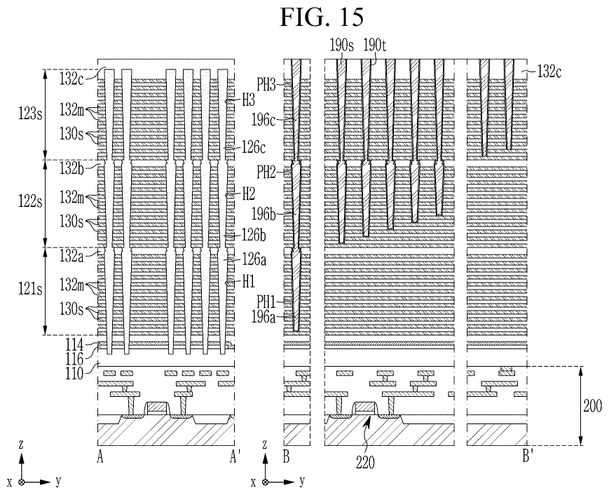

Next, referring to FIG. 15, a protective insulation layer 190t and a penetration sacrificial layer 190s may be formed within the gate penetration portion PH. At this stage, the first sacrificial gate contact portion 196a may be formed by filling the first gate penetration portion PH1 with the protective insulation layer 190t and the penetration sacrificial layer 190s.

A protective insulation layer 190t may be formed inside the plurality of gate penetration portions PH. For example, the protective insulation layer 190t may be formed on the inner surface and the bottom surface of each of the plurality of gate penetration portions PH. The process of forming the protective insulation layer 190t may be performed by various processes (e.g., a deposition process, etc.). However, the implementation is not limited thereto.

After forming the protective insulation layer 190t, a penetration sacrificial layer 190s may be formed on the protective insulation layer 190t within the plurality of gate penetration portion PH. The penetration sacrificial layer 190s may include at least one of a metallic material or a non-metallic material, for example, polycrystalline silicon, tungsten, titanium nitride, and carbon. However, the implementation is not limited thereto and the penetration sacrificial layer 190s may include various materials.

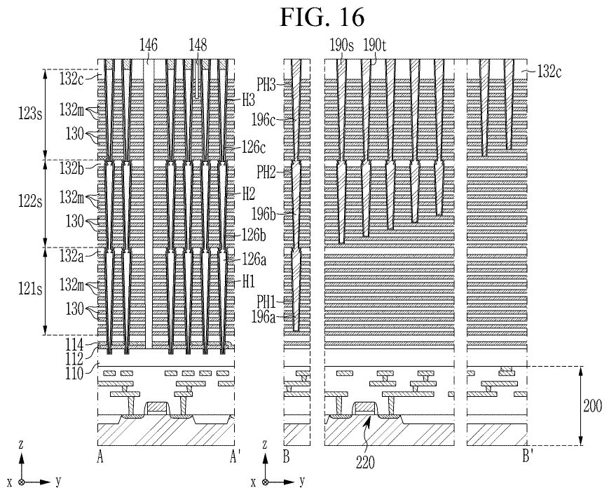

Next, as shown in FIG. 16, the channel structure CH, the gate electrode 130, and the isolation structure 146 may be formed.

In further detail, the sacrificial material filling the first channel penetration portion H1, the second channel penetration portion H2, and the third channel penetration portion H3 may be removed, and a gate dielectric layer (the reference numeral 150 of FIG. 2, the same applies hereinafter), a channel layer (the reference numeral 140 of FIG. 2, the same applies hereinafter), a core insulation layer (the reference numeral 142 of FIG. 2, the same applies hereinafter) may be sequentially formed, and a channel pad (the reference numeral 144 of FIG. 2, the same applies hereinafter) may be formed inside the first channel penetration portion H1, the second channel penetration portion H2 and the third channel penetration portion H3

The process of forming the gate dielectric layer 150, the channel layer 140, the core insulation layer 142, or the channel pad 144 may be performed by various processes (e.g., a deposition process, etc.).

An opening for an isolation structure may be formed in a region corresponding to the isolation structure 146 so as to penetrate the first sacrificial stacked portion 121s, the second sacrificial stacked portion 122s, and the third sacrificial stacked portion 123s, and the sacrificial insulation layer (the reference numeral 130s of FIG. 15) may be replaced with a gate electrode 130, and the opening for the isolation structure may be filled with an insulating material, etc., to form the isolation structure 146.

In some implementations, the opening for the isolation structure may be formed by various processes (e.g., an etching process, etc.). The sacrificial insulation layer 130s may be selectively removed by an etching process (e.g., a wet etching process) through the opening for the isolation structure. A gate electrode 130 may be formed by filling a conductive material in the region where the sacrificial insulation layer 130s has been removed. In this way, the region where the sacrificial insulation layer 130s is positioned may be replaced with the gate electrode 130. At this time, a process of forming a part (e.g., the first blocking layer (the reference numeral 156a of FIG. 2)) of the blocking layer (the reference numeral 156 of FIG. 2) may be further performed prior to the process of filling the conductive material forming the gate electrode 130. However, the implementation is not limited thereto. The process of filling the opening for the isolation structure may be performed by various processes (e.g., a deposition process, etc.).

According to the implementation, the opening for the isolation structure may be formed to expose the horizontal insulation layer 116. In the etching process through the opening for the isolation structure, at least a portion of the horizontal insulation layer 116 and a portion of the gate dielectric layer 150 may be removed, and the material constituting the first horizontal conductive layer 112 may be filled to form the first horizontal conductive layer 112.

According to the implementation, an upper isolation region 148 may be formed in a part of the gate stacking structure 120. The upper isolation region 148 may be formed by forming an opening for an isolation pattern by an etching process using a mask layer and filling at least a portion of the opening for the isolation pattern with an insulating material. The process for forming the opening for the isolation pattern may be performed by various processes (e.g., an etching process, etc.). The process of forming an insulating material within the opening for the isolation pattern may be performed by various processes (e.g., a deposition process, etc.). The process for forming the opening for the isolation pattern and the process for forming an insulating material within the opening for the isolation pattern may be performed by various process sequences.

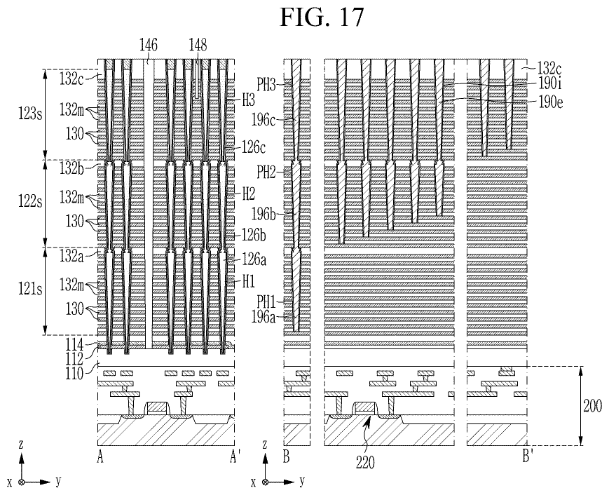

Next, as shown in FIG. 17, the penetration sacrificial layer (the reference number 190s in FIG. 15, the same applies hereinafter) is removed, and the lower part (i.e., the part positioned on the upper surface of the gate electrode 130) of the protective insulation layer (the reference symbol 190t of FIG. 15, the same applies hereinafter) may be removed to form a side insulation layer 190i. Also, the gate penetration portion PH may be filled with a conductive material to form a conductive portion. In this way, the gate contact part 190 may be formed.

The process of removing the penetration sacrificial layer 190s may be performed by various processes (e.g., an etching process, etc.), the process of removing the lower portion of the protective insulation layer 190t may be performed by various processes (e.g., an etching process, etc.), and the process of forming the conductive portion may be performed by various processes (e.g., a deposition process, etc.).

Next, a cell wire part such as the bit line connected to the channel structure CH may be formed to form the semiconductor device as shown in FIG. 1.

As described above, in the manufacturing method of the semiconductor device according to the present implementation, in the forming process of the first channel penetration portion H1, the second channel penetration portion H2, and the third channel penetration portion H3 of the cell array region 102, the process may be simplified by simultaneously forming the part of the gate penetration portions PH2 and PH3 of the connection region 104.

In a structure that does not have a part (e.g., a part having a step shape) where the gate stacking structure 120 is removed for the electrical connection between the gate electrode 130 and the gate contact part 190, a complex process may be required to form the gate contact part 190 that reaches each gate electrode 130. However, in the present implementation, the process is simplified by pre-etching the portion of the gate contact part by using the etching stop pattern. In addition, for a prior known manufacturing process, it was necessary to make the thickness of the first upper insulation layer 130a and the second upper insulation layer 130b similar to that of the interlayer insulating layer 130m. This is because in the process of simultaneously etching the multiple layers of the insulation layers, the thickness of the insulation layers of each layer should be similar in order to form the gate contact part up to the desired gate electrode. In this case, when the thickness of the first upper insulation layer 130a and the second upper insulation layer 130b are similar to that of the interlayer insulating layer 130m, there may be a problem of an insufficient margin due to a misalignment at the boundaries of the gate contact portions formed by the different processes. However, in the case of the present implementation, the etching stop pattern is positioned on the first upper insulation layer 130a and the second upper insulation layer 130b, so the thickness of the first upper insulation layer 130a and the second upper insulation layer 130b may be thicker than the interlayer insulating layer 130m, and therefore, a sufficient margin due to misalignment may be secured at the boundary of each gate contact portion.

An example of an electron system including the semiconductor device as described above is described in detail as follows.

FIG. 18 is a schematic drawing of an electron system including a semiconductor device according to an exemplary implementation.

Referring to FIG. 18, an electron system 1000 according to an implementation may include a semiconductor device 1100 and a controller 1200 electrically connected to the semiconductor device 1100. The electron system 1000 may be a storage device including one or the plurality of semiconductor devices 1100 or an electronic device including the storage device. For example, the electron system 1000 may be a solid state drive device (SSD), a universal serial bus (USB), a computing system, a medical device or a communication apparatus including one or the plurality of semiconductor devices 1100.

The semiconductor device 1100 may be a non-volatile memory device, and may be a NAND flash memory device, for example, as referred to FIG. 1 to FIG. 18. The semiconductor device 1100 may include a first structure 1100F and a second structure 1100S on the first structure 1100F. In some implementations, the first structure 1100F may be placed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each memory cell strings CSTR may include lower transistors LT1 and LT2 adjacent to the common source line CSL, upper transistors UT1 and UT2 adjacent to the bit line BL, and a plurality of memory cell transistors MCT arranged between the lower transistor LT1 and LT2, and the upper transistors UT1 and UT2. The number of the lower transistors LT1 and LT2 and the number of the upper transistors UT1 and UT2 may vary according to the implementation.

In some implementations, the lower transistors LT1 and LT2 may include a ground selection transistor, and the upper transistors UT1 and UT2 may include a string selection transistor. The first and second gate lower lines LL1 and LL2 may be the gate electrodes of the lower transistors LT1 and LT2, respectively. The word line WL may be the gate electrode of the memory cell transistor MCT, and the gate upper lines UL1 and UL2 may be the gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 via the first connection wire 1115 extending from the first structure 1100F to the second structure 1100S. The bit line BL may be electrically connected to the page buffer 1120 through a second connection wire 1125 that extends from the first structure 1100F to the second structure 1100S.

In the first structure 1100F, the decoder circuit 1110 and the page buffer 1120 may perform a control operation on at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 via the input/output connection wire 1135, which extends from the first structure 1100F to the second structure 1100S.

The controller 1200 may include a processor 1210, a NAND controller 1220, and a host interface 1230. According to some implementations, the electron system 1000 may include a plurality of semiconductor devices 1100, in this case, the controller 1200 may control the plurality of semiconductor devices 1100.

The processor 1210 may control the operation of the entire electron system 1000, including the controller 1200. The processor 1210 may operate according to a predetermined firmware and control the NAND controller 1220 to access the semiconductor device 1100. The NAND controller 1220 may include a NAND interface 1221 that handles the communications with the semiconductor device 1100. Through the NAND interface 1221, control instructions for controlling the semiconductor device 1100, a data to be written to the memory cell transistor MCT of the semiconductor device 1100, a data to be read from the memory cell transistor MCT of the semiconductor device 1100, etc. may be transmitted. The host interface 1230 may provide communication functions between the electron system 1000 and an external host. When receiving the control instruction from the external host through the host interface 1230, the processor 1210 may respond to the control instruction to control the semiconductor device 1100.

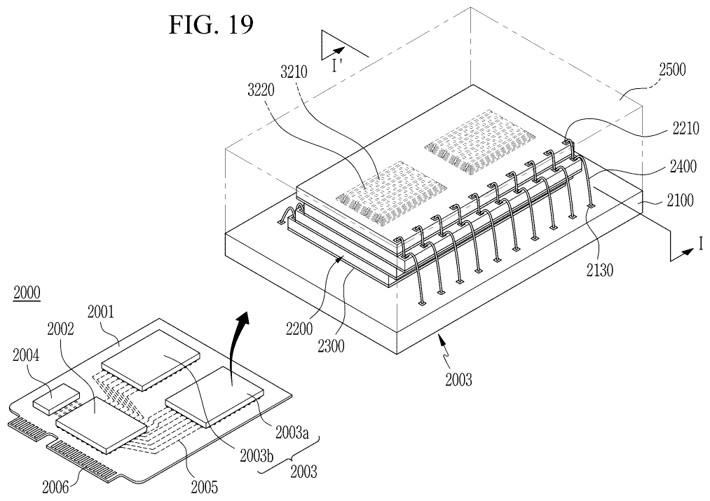

FIG. 19 is a perspective view schematically illustrating an electron system including a semiconductor device according to some implementations.

Referring to FIG. 19, an electron system 2000 according to some implementations may include a main substrate 2001, and a controller 2002, one or more semiconductor packages 2003, and a DRAM 2004 mounted on the main substrate 2001. The semiconductor package 2003 and the DRAM 2004 may be interconnected with the controller 2002 by the wire pattern 2005 formed on the main substrate 2001.

The main substrate 2001 may include a connector 2006 including a plurality of pins that couple to an external host. The number and arrangement of the pins in the connector 2006 may vary depending on the communication interface between the electron system 2000 and the external host. In some implementations, the electron system 2000 may communicate with the external host via any one of following interfaces such as a universal serial bus (USB), a peripheral component interconnect express (PCI-express), a serial advanced technology attachment (SATA), or an M-Phy for a universal flash storage (UFS). In some implementations, the electron system 2000 may be operated by a power supplied from the external host via the connector 2006. The electron system 2000 may further include a power management integrated circuit (PMIC) that distributes a power supplied from the external host to the controller 2002 and the semiconductor package 2003.

The controller 2002 may write a data to or read a data from the semiconductor package 2003, and improve the operation speed of the electron system 2000.

The DRAM 2004 may be a buffer memory to alleviate the speed difference between the semiconductor package 2003, which is the data storage space, and the external host. The DRAM 2004 included in the electron system 2000 may also function as a type of a cache memory and provide a space to temporarily store a data in control operations for the semiconductor package 2003. When the electron system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b which are spaced apart from each other. The first and second semiconductor packages 2003a and 2003b may each be a semiconductor package including the plurality of semiconductor chips 2200. The first and second semiconductor packages 2003a and 2003b may each include a package substrate 2100, a semiconductor chip 2200 on the package substrate 2100, an adhesive layer 2300 disposed on the bottom surface of each of the semiconductor chips 2200, a connection structure 2400 electrically connecting the semiconductor chip 2200 and the package substrate 2100, and a molding layer 2500 covering the semiconductor chip 2200 and the connection structure 2400 on the package substrate 2100.

The package substrate 2100 may be a printed circuit board (PCB) including a package upper pad 2130. Each semiconductor chip 2200 may include an input/output pad 2210. The input/output pad 2210 may correspond to the input/output pad 1101 of FIG. 29. Each semiconductor chip 2200 may include a gate stacking structure 3210 and a channel structure 3220. The semiconductor chip 2200 may each include a semiconductor device as described with reference to FIG. 1 to FIG. 18.

In some implementations, the connection structure 2400 may be a bonding wire that electrically connects the input/output pad 2210 and the package upper pad 2130. Therefore, in each of the first and second semiconductor packages 2003a and 2003b, the semiconductor chips 2200 may be electrically connected to each other in a bonding wire manner and may be electrically connected to the package upper pad 2130 of the package substrate 2100. According to the implementation, in each of the first and second semiconductor packages 2003a and 2003b, the semiconductor chips 2200 may be electrically connected to each other by a connection structure including a through electrode (a through silicon via, TSV) instead of the connection structure 2400 of a bonding wire-type.

In some implementations, the controller 2002 and the semiconductor chip 2200 may be included in a single package. For example, the controller 2002 and the semiconductor chip 2200 may be mounted on a separate interposer substrate from the main substrate 2001, and the controller 2002 and the semiconductor chip 2200 may be connected to each other by wires formed on the interposer substrate.

FIG. 20 is a cross-sectional view schematically illustrating a semiconductor package according to some implementations. FIG. 20 illustrates an implementation of the semiconductor package 2003 of FIG. 19, conceptually illustrating a region cut along a section line I-I′ of the semiconductor package 2003 of FIG. 19.

Referring to FIG. 20, in the semiconductor package 2003, the package substrate 2100 may be a printed circuit board (PCB). The package substrate 2100 may include a package substrate body portion 2120, a package upper pad 2130 disposed on the upper surface of the package substrate body portion 2120, a package lower pad 2125 disposed on the bottom surface of the package substrate body portion 2120 or exposed through the bottom surface, and an inner wire 2135 electrically connecting the package upper pad 2130 and the package lower pad 2125 within the package substrate body portion 2120. The package upper pad 2130 may be electrically connected to the connection structure 2400. The package lower pad 2125 may be connected to the wire pattern 2005 of the main substrate 2001 of the electron system 2000 as shown in FIG. 29 via a conductive connection 2800.

The semiconductor chip 2200 may each include a semiconductor substrate 3010 and a first structure 3100 and a second structure 3200 sequentially stacked on the semiconductor substrate 3010. The first structure 3100 may include a peripheral circuit region including peripheral wires 3110. The second structure 3200 may include a common source line 3205, a gate stacking structure 3210 on the common source line 3205, a channel structure 3220 and an isolation structure 3230 penetrating the gate stacking structure 3210, a bit line 3240 electrically connected to the channel structure 3220, and a gate connection wire electrically connected to a word line WL (the reference numeral of FIG. 29) of the gate stacking structure 3210.

In the semiconductor chip 2200 or the semiconductor device according to the implementation, a part of the gate penetration portion of the connection region is formed simultaneously in the forming process of the channel penetration portion of the cell array region. Therefore, the manufacturing process may be simplified by reducing the number of the partial etching processes for etching the gate penetration portion. By this process, the gate penetration portion may include the stepped part by the formation and the removal of the etching stop pattern.

Each of the semiconductor chips 2200 may include the through wire 3245 that is electrically connected to the peripheral wire 3110 of the first structure 3100 and extends into the second structure 3200. The through wire 3245 may pass through the gate stacking structure 3210 and may be further arranged on the outside of the gate stacking structure 3210. Each of the semiconductor chips 2200 may further include an input/output connection wire 3265 that is electrically connected to the peripheral wire 3110 of the first structure 3100 and extends into the second structure 3200, and an input/output pad 2210 that is electrically connected to the input/output connection wire 3265.

In some implementations, the plurality of semiconductor chips 2200 in the semiconductor package 2003 may be electrically connected to each other by the connection structure 2400 in a form of a bonding wire. As another example, the plurality of semiconductor chip 2200 or a plurality of parts constituting the same may be electrically connected by a connection structure including a through electrode.

Although the implementation has been described in detail above, the scope of the present invention is not limited thereto. Various modifications and improvements of a person of ordinary skill in the art utilizing the basic concept of the present invention defined in the scope of the claim may also fall within the scope of the present invention.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
a substrate;
a gate stacking structure comprising a plurality of interlayer insulating layers and a plurality of gate electrodes, wherein each of the plurality of interlayer insulating layers and each of the plurality of gate electrodes are alternately stacked on the substrate;
a channel structure extending through the gate stacking structure; and
a plurality of gate contact parts, each gate contact part (i) extending into at least a portion of the gate stacking structure and (ii) connected to a respective gate electrode of the plurality gate electrodes,
wherein the gate stacking structure comprises a first gate stacking structure, a second gate stacking structure, and a first upper insulation layer that is between the first gate stacking structure and the second gate stacking structure,
wherein the first gate stacking structure, the second gate stacking structure, and the first upper insulation layer are sequentially stacked on the substrate,
wherein at least one first gate contact part of the plurality of gate contact parts is connected to a respective first gate electrode of the first gate stacking structure,
wherein each of the at least one first gate contact part comprises a stepped part and a bent part,
wherein a width of each of the at least one first gate contact part changes discontinuously, and
wherein the stepped part and bent part are within the first upper insulation layer.

2. The semiconductor device of claim 1, wherein each of the at least one first gate contact part comprises a first connection part extending into the first gate stacking structure and a second connection part extending into the second gate stacking structure, and
wherein the stepped part is between the first connection part and the second connection part.

3. The semiconductor device of claim 2, wherein the stepped part has a width that at least partially decreases toward the substrate, and
wherein a lower surface of the stepped part is within the first upper insulation layer.

4. The semiconductor device of claim 3, wherein each of the first connection part and the second connection part has a width that at least partially decreases toward the substrate, and
wherein the bent part is between the first connection part and the second connection part, and
wherein a width of the bent part is different from a width of each of an upper surface of the first connection part and a lower surface of the second connection part.

5. The semiconductor device of claim 4, wherein the bent part is closer to the substrate than the stepped part.

6. The semiconductor device of claim 1, wherein the channel structure comprises (i) a first channel portion extending into the first gate stacking structure, (ii) a second channel portion extending into the second gate stacking structure, and (iii) a channel stepped part between the first channel portion and the second channel portion.

7. The semiconductor device of claim 6, wherein a width of the channel stepped part at least partially decreases toward the substrate, and
wherein a lower surface of the channel stepped part is within the first upper insulation layer.

8. The semiconductor device of claim 7, wherein a width of each of the first channel portion and the second channel portion at least partially decreases toward the substrate,
wherein a channel bent part is between the first channel portion and the second channel portion, and
wherein a portion of the channel bent part is defined at least based on a difference in widths between an upper surface of the first channel portion and a lower surface of the second channel portion.

9. The semiconductor device of claim 8, wherein the channel bent part is closer to the substrate than the channel stepped part.

10. The semiconductor device of claim 1, wherein the gate stacking structure comprises a second upper insulation layer on the second gate stacking structure and a third gate stacking structure on the second upper insulation layer, and
wherein each of the at least one first gate contact part comprises a second stepped part and a second bent part that are within the second upper insulation layer.

11. The semiconductor device of claim 10, wherein at least one second gate contact part of the plurality of gate contact parts is connected to a respective second gate electrode of the second gate stacking structure, and
wherein the at least one second gate contact part extends into the second gate stacking structure and the third gate stacking structure,
wherein each of the at least one second gate contact part comprises a stepped part and a bent part that are within the second upper insulation layer, and
wherein a width of each of the at least one second gate contact part changes discontinuously.

12. The semiconductor device of claim 10, wherein at least one third gate contact part of the plurality of gate contact parts is connected to a respective third gate electrode of the third gate stacking structure, and
wherein each of the at least one third gate contact part extends into at least a portion of the plurality of gate electrodes of the third gate stacking structure.

13. The semiconductor device of claim 1, wherein the gate stacking structure comprises a second upper insulation layer on the second gate stacking structure, and
wherein a thickness of each of the first upper insulation layer and the second upper insulation layer is greater than a thickness of each interlayer insulating layer.

14. The semiconductor device of claim 1, wherein the gate stacking structure comprises a cell array region and a connection region, the channel structure being at the cell array region and the plurality of gate contact parts being at the connection region, and
wherein at least a portion of each of the plurality of gate contact parts extends into respective second gate electrodes that are above a respective gate electrode that is connected to each gate contact part at the connection region.

15. A semiconductor device comprising:
a substrate;
a gate stacking structure comprising a plurality of interlayer insulating layers and a plurality of gate electrodes, wherein each of the plurality of interlayer insulating layers and each of the plurality of gate electrodes are alternately stacked on the substrate, wherein the gate stacking structure comprises a first gate stacking structure, a second gate stacking structure, and a third gate stacking structure that are sequentially stacked on the substrate;
a channel structure extending through the gate stacking structure;
a plurality of gate contact parts, each gate contact part (i) extending into a portion of the gate stacking structure and (ii) connected to a respective gate electrode of the plurality of gate electrodes;
a first upper insulation layer between the first gate stacking structure and the second gate stacking structure; and
a second upper insulation layer between the second gate stacking structure and the third gate stacking structure,
wherein a first gate contact part of the plurality of gate contact parts is connected to a first gate electrode of the plurality of gate electrodes that is in the first gate stacking structure,
wherein the first gate contact part comprises:
a first bent part and a first stepped part that are within the first upper insulation layer, and
a second bent part and a second stepped part that are within the second upper insulation layer,
wherein a second gate contact part of the plurality of gate contact parts is connected to a second gate electrode of the plurality of gate electrodes that is in the second gate stacking structure,
wherein the second gate contact part comprises:
a third bent part and a third stepped part that are within the second upper insulation layer, and
wherein a third gate contact part of the plurality of contact parts is (i) connected to a third gate electrode of the plurality of gate electrodes that is in the third gate stacking structure and (ii) extends into at least a portion of the third gate stacking structure.

16. The semiconductor device of claim 15, wherein a width of each of the first stepped part, the second stepped part, and the third stepped part at least partially decreases toward the substrate.

17. The semiconductor device of claim 16, wherein each of the first bent part, the second bent part, and the third bent part is closer to the substrate than a respective stepped part of the first stepped part, the second stepped part, and the third stepped part.

18. The semiconductor device of claim 15, wherein a thickness of each of the first upper insulation layer and the second upper insulation layer is greater than a thickness of each interlayer insulating layer.

19. The semiconductor device of claim 15, wherein the gate stacking structure comprises a cell array region and a connection region, the channel structure being at the cell array region and the plurality of gate contact parts being at the connection region, and
wherein at least a portion of each of the plurality of gate contact parts extends into fourth gate electrodes that are above a respective gate electrode connected to each gate contact part at the connection region.

20. An electron system comprising:
a main substrate;
a semiconductor device on the main substrate; and
a controller connected to the semiconductor device on the main substrate,
wherein the semiconductor device comprises:
a substrate,
a gate stacking structure comprising a plurality of interlayer insulating layers and a plurality of gate electrodes, each of the plurality of interlayer insulating layers and each of the plurality of gate electrodes being alternately stacked on the substrate,
a channel structure extending through the gate stacking structure, and
a plurality of gate contact parts, each gate contact part (i) extending into a portion of the gate stacking structure and (ii) connected to a respective gate electrode, of the plurality of gate electrodes,
wherein the gate stacking structure comprises a first gate stacking structure and a second gate stacking structure that are stacked with a first upper insulation layer therebetween, and
wherein at least one first gate contact part of the plurality of gate contact parts is connected to a first gate electrode of the first gate stacking structure,
wherein each of the at least one first gate contact part comprises a stepped part and a bent part that are within the first upper insulation layer, and
wherein a width of each of the at least one first gate contact part changes discontinuously.
